(19) United States
(12) Patent Application Publication
(10) Pub. No.: US 2012/0001167 A1
(43) Pub. Date: Jan. 5, 2012

(54) THIN FILM TRANSISTOR AND DISPLAY DEVICE

(75) Inventor: Narihiro Morosawa, Kanagawa (JP)

(73) Assignee: SONY CORPORATION, Tokyo (JP)

(21) Appl. No.: 13/151,315

(22) Filed: Jun. 2, 2011

(30) Foreign Application Priority Data
Jul. 5, 2010 (JP) 2010-152754

(51) Int. Cl. H01L 29/786

(52) U.S. Cl. 257/43; 257/E29.296

(57) ABSTRACT

A thin film transistor allowed to suppress a failure caused by an interlayer insulating film and improve reliability of a self-alignment structure, and a display device including this thin film transistor are provided. The thin film transistor includes: a gate electrode; an oxide semiconductor film having a channel region facing the gate electrode, and having a source region on one side of the channel region, and a drain region on the other side of the channel region; an interlayer insulating film provided in contact with the oxide semiconductor film as well as having a connection hole, and including an organic resin film; and a source electrode and a drain electrode connected to the source region and the drain region, respectively, via the connection hole.

### BACKGROUND

The present disclosure relates to a thin film transistor (TFT) using an oxide semiconductor and a display device including this TFT.

In a liquid crystal display or an organic EL (Electroluminescence) display which employ an active drive system, a thin film transistor is used as a driving element and electric charge corresponding to a signal voltage for writing an image is held in a retention capacitor. However, when parasitic capacitance occurring in a cross region between a gate electrode and a source electrode or a drain electrode of the thin film transistor becomes large, the signal voltage fluctuates, which may cause a deterioration in image quality.

In particular, in the organic EL display, when the parasitic capacitance is large, it is desirable to make the retention capacitor large as well, and the proportion of wirings and the like in a pixel layout increases. As a result, the probability of occurrence of a short or the like between the wirings may increase and thereby a production yield may be reduced.

Therefore, for a thin film transistor using, for example, an oxide semiconductor of zinc oxide (ZnO), indium gallium zinc oxide (IGZO), or the like as a channel, there is being made an attempt to reduce parasitic capacitance formed in a cross region between a gate electrode and a source electrode or a drain electrode.

For example, each of Japanese Unexamined Patent Application Publication No. 2007-220817 and a document titled “Self-aligned top-gate amorphous gallium indium zinc oxide thin film transistors” (Applied Physics Letters, American Institute of Physics, 2008, Vol. 93, 053501, by J. Park and eleven others), describes a self-aligned top-gate thin film transistor. In this thin film transistor, on a channel region of an oxide semiconductor thin layer, a gate electrode and a gate insulating film are formed to be of the same shape and then, a source-drain region is formed by reducing the resistance of a region not covered by the gate electrode and the gate insulating film of the oxide semiconductor thin layer. Further, a document titled “Improved Amorphous In—Ga—Zn—O TFTs” (SID 08 DIGEST, 2008 42.1, p. 621-624, by R. Hayashi and six others), describes a bottom-gate thin film transistor having a self-alignment structure in which a source region and a drain region are formed in an oxide semiconductor film by backside exposure using a gate electrode as a mask.

### SUMMARY

However, in the Japanese Unexamined Patent Application Publication No. 2007-220817 and the document titled “Self-aligned top-gate amorphous gallium indium zinc oxide thin film transistors” (Applied Physics Letters, American Institute of Physics, 2008, Vol. 93, 053501, by J. Park and eleven others) mentioned above, an interlayer insulating film is formed after etching of the gate electrode and the gate insulating film and thus, there is a case in which a large step equivalent to the total thickness of the gate electrode and the gate insulating film after the etching is formed, and it is difficult to cover the step with the interlayer insulating film made of only an insulating film formed by an ordinary plasma CVD method. Therefore, there is such a disadvantage that a failure such as disconnection of a source electrode and a drain electrode, which are subsequently formed, or a short may easily occur. In addition, in the above-mentioned document titled “Improved Amorphous In—Ga—Zn—O TFTs” (SID 08 DIGEST, 2008 42.1, p. 621-624, by R. Hayashi and six others), an interlayer insulating film is formed after etching of a channel protective film and therefore, a step equivalent to the thickness of the channel protective film after the etching is formed and thus, there is a disadvantage similar to that of Japanese Unexamined Patent Application Publication No. 2007-220817 and the document titled “Self-aligned top-gate amorphous gallium indium zinc oxide thin film transistors” (Applied Physics Letters, American Institute of Physics, 2008, Vol. 93, 053501, by J. Park and eleven others).

In view of the foregoing, it is desirable to provide a thin film transistor allowed to suppress a failure caused by an interlayer insulating film and improve reliability of a self-alignment structure, and it is also desirable to provide a display device including this thin film transistor.

A thin film transistor according to an embodiment of the present disclosure includes the following (A) to (D):

(A) a gate electrode;
(B) an oxide semiconductor film having a channel region facing the gate electrode, and having a source region on one side of the channel region, and a drain region on the other side of the channel region;
(C) a interlayer insulating film provided in contact with the oxide semiconductor film as well as having a connection hole, and including an organic resin film; and
(D) a source electrode and a drain electrode connected to the source region and the drain region, respectively, via the connection hole.

In the thin-film transistor according to the embodiment of the present disclosure, the interlayer insulating film includes the organic resin film. Therefore, it is possible to increase the thickness of the interlayer insulating film, and suppress a failure due to the interlayer insulating film, such as disconnection of the source electrode and the drain electrode or a short.

A display device according to an embodiment of the present disclosure includes a thin film transistor and a pixel, and this thin film transistor is configured by employing the thin film transistor according to the earlier-described embodiment of the present disclosure.

In the display device according to this embodiment of the present disclosure, the pixel is driven by the thin film transistor in the earlier-described embodiment of the present disclosure, and thereby an image is displayed.

According to the thin film transistor of the embodiment of the present disclosure, the interlayer insulating film includes the organic resin film. Therefore, it is possible to suppress a failure due to the interlayer insulating film, such as disconnection of the source electrode and the drain electrode or a short, thereby improving reliability of a self-alignment structure. Accordingly, when a display device is configured by using this thin film transistor, high-quality display may be realized by this thin film transistor having the self-alignment structure with small parasitic capacitance as well as having high reliability.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification.

The drawings illustrate embodiments and, together with the specification, serve to explain the principles of the technology.

FIG. 1 is a cross-sectional diagram illustrating a structure of a thin film transistor according to a first embodiment of the present disclosure.

FIGS. 2A to 2C are cross-sectional diagrams illustrating a method of producing the thin film transistor illustrated in FIG. 1, in process order.

FIGS. 3A to 3C are cross-sectional diagrams illustrating a process following FIG. 2C.

FIG. 4 is a diagram illustrating an EDX analysis result of a channel region and a low-resistance region.

FIGS. 5A and 5B are diagrams each illustrating a characteristic of the thin film transistor illustrated in FIG. 1, compared to that in a related art.

FIGS. 6A to 6C are cross-sectional diagrams illustrating a method of producing a thin film transistor according to a modification 1, in process order.

FIG. 7 is a cross-sectional diagram illustrating a process following FIG. 6C.

FIGS. 8A to 8C are cross-sectional diagrams illustrating a method of producing a thin film transistor according to a modification 2, in process order.

FIGS. 9A and 9B are cross-sectional diagrams illustrating a method of producing a thin film transistor according to a modification 3, in process order.

FIG. 10 is a cross-sectional diagram illustrating a structure of a thin film transistor according to a modification 4.

FIGS. 11A to 11D are cross-sectional diagrams illustrating a method of producing the thin film transistor illustrated in FIG. 10, in process order.

FIGS. 12A to 12C are cross-sectional diagrams illustrating a process following FIG. 11D.

FIG. 13 is a cross-sectional diagram illustrating a process following FIG. 12C.

FIGS. 14A to 14E are cross-sectional diagrams illustrating a method of producing a thin film transistor according to a modification 5, in process order.

FIG. 15 is a cross-sectional diagram illustrating a structure of a thin film transistor according to a second embodiment of the present disclosure.

FIGS. 16A and 16B are cross-sectional diagrams illustrating a method of producing the thin film transistor illustrated in FIG. 15, in process order.

FIG. 17 is a cross-sectional diagram illustrating a structure of a thin film transistor according to a third embodiment of the present disclosure.

FIG. 18 is a cross-sectional diagram illustrating a structure of a thin film transistor according to a fourth embodiment of the present disclosure.

FIGS. 19A to 19D are cross-sectional diagrams illustrating a method of producing the thin film transistor illustrated in FIG. 18, in process order.

FIGS. 20A and 20B are cross-sectional diagrams illustrating a process following FIG. 19D.

FIG. 21 is a cross-sectional diagram illustrating a structure of a thin film transistor according to a fifth embodiment of the present disclosure.

FIG. 22 is a cross-sectional diagram illustrating a structure of a thin film transistor according to a sixth embodiment of the present disclosure.

FIG. 23 is a diagram illustrating a circuit configuration of a display device according to an application example 1.

FIG. 24 is an equivalent circuit diagram illustrating an example of a pixel driving circuit illustrated in FIG. 23.

FIG. 25 is a perspective diagram illustrating an appearance of an application example 2.

FIGS. 26A and 26B are a perspective diagram illustrating an appearance of an application example 3 viewed from a front side, and a perspective diagram illustrating an appearance of the application example 3 viewed from a rear side, respectively.

FIG. 27 is a perspective diagram illustrating an appearance of an application example 4.

FIG. 28 is a perspective diagram illustrating an appearance of an application example 5.

FIGS. 29A to 29G are diagrams illustrating an application example 6, and specifically, FIG. 29A is a front view in an open state, FIG. 29B is a side view in the open state, FIG. 29C is a front view in a closed state, FIG. 29D is a left-side view, FIG. 29E is a right-side view, FIG. 29F is a top view, and FIG. 29G is a bottom view.

FIG. 30 is a cross-sectional diagram illustrating a modification of the thin film transistor illustrated in FIG. 1.

### DETAILED DESCRIPTION OF EMBODIMENTS

Embodiments of the present disclosure will be described below in detail with reference to the drawings. Incidentally, the description will be provided in the following order.

1. First embodiment (a top-gate thin film transistor: an example in which an interlayer insulating film has a two-layer structure including a first inorganic insulating film and an organic resin film, and the first inorganic insulating film is formed by oxidization of a metal film.)
2. Modification 1 (an example in which a first inorganic insulating film is formed by laminating a metal film and a metal oxide film, and oxidizing this metal film.)
3. Modification 2 (an example in which a low-resistance region is formed by using plasma.)
4. Modification 3 (an example in which a low-resistance region is formed by diffusion of hydrogen from a silicon nitride film.)
5. Modification 4 (an example in which an oxide semiconductor film is made by forming a laminated film including an amorphous film and a crystallized film, and processing this laminated film by etching.)
6. Modification 5 (an example in which an oxide semiconductor film is made by forming a laminated film including an amorphous film and an amorphous film; processing this laminated film by etching; and then forming a crystallized film by annealing the upper amorphous film.)
7. Second embodiment (a top-gate thin film transistor: an example in which an interlayer insulating film is formed of only an organic resin film.)
8. Third embodiment (a top-gate thin film transistor: an example in which an interlayer insulating film has a three-layer structure including a first inorganic insulating film, an organic resin film, and a second inorganic insulating film, and the first inorganic insulating film is formed by oxidization of a metal film.)
9. Fourth embodiment (an example in which a metal film is removed after being oxidized and, an interlayer insulating film has a two-layer structure including an organic resin film and a second inorganic insulating film.)
10. Fifth embodiment (a bottom-gate thin film transistor: an example in which an interlayer insulating film has a two-layer structure including a first inorganic insulating film and an organic resin film, and the first inorganic insulating film is formed by oxidization of a metal film.)
11. Sixth embodiment (a bottom-gate thin film transistor: an example in which an interlayer insulating film is formed of only an organic resin film.)
12. Seventh embodiment (a bottom-gate thin film transistor: an example in which an interlayer insulating film has a three-layer structure including a first inorganic insulating film, an organic resin film, and a second inorganic insulating film, and the first inorganic insulating film is formed by oxidization of a metal film.)
13. Eighth embodiment (an example in which a metal film is removed after being oxidized and, an interlayer insulating film has a two-layer structure including an organic resin film and a second inorganic insulating film.)

### 14. Application Examples

### FIRST EMBODIMENT

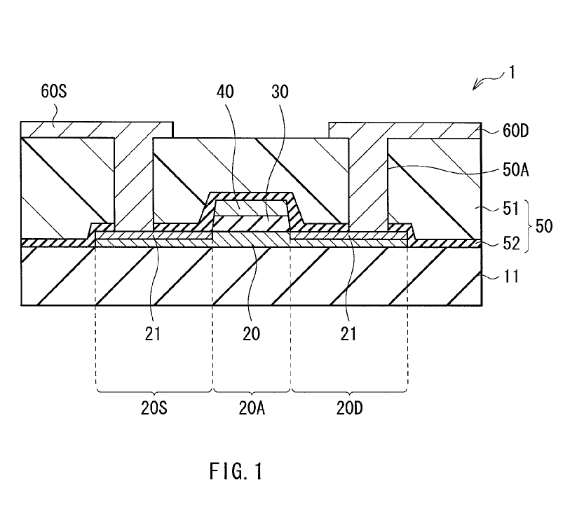

FIG. 1 illustrates a cross-sectional structure of a thin film transistor 1 according to the first embodiment of the present disclosure. The thin film transistor 1 is used as a driving element of a liquid crystal display, an organic EL display, or the like, and has, for example, a top-gate type (staggered type) structure in which an oxide semiconductor film 20, a gate insulating film 30, a gate electrode 40, an interlayer insulating film 50, a source electrode 60S, and a drain electrode 60D are laminated in this order on a substrate 11.

The substrate 11 is made of, for example, a glass substrate, a plastic film, or the like. Examples of a plastic material include PET (polyethylene terephthalate), PEN (polyethylene naphthalate), and the like. In a sputtering method to be described later, the oxide semiconductor film 20 is formed without heating the substrate 11 and thus, an inexpensive plastic film may be used. Further, the substrate 11 may be a metal substrate made of stainless steel (SUS) or the like, depending on the purpose.

The oxide semiconductor film 20 is disposed on the substrate 11 and shaped like an island including the gate electrode 40 and its neighborhood, and functions as an active layer of the thin film transistor 1. For example, the oxide semiconductor film 20 has a thickness of around 50 nm, and includes a channel region 20A facing the gate electrode 40. On the channel region 20A, the gate insulating film 30 and the gate electrode 40 identical in shape are disposed in this order. A source region 20S is provided on one side of the channel region 20A, and a drain region 20D is provided on the other side. In other words, this thin film transistor 1 has a self-alignment structure.

The channel region 20A is made of an oxide semiconductor. The oxide semiconductor is a compound including oxygen and elements such as indium, gallium, zinc, and tin. Specifically, as an amorphous oxide semiconductor, there is indium gallium zinc oxide (IGZO), and examples of a crystalline oxide semiconductor include zinc oxide (ZnO), indium zinc oxide (IZO (trademark)), indium gallium oxide (IGO), indium tin oxide (ITO), and indium oxide (InO).

The source region 20S and the drain region 20D each have a low-resistance region 21 in a part in a depth direction from a top surface.

For example, the low-resistance region 21 is made to have a low resistance by being provided with an oxygen concentration lower than that of the channel region 20A. It is desirable that the oxygen concentration included in the low-resistance region 21 be equal to or less than 30%. This is because when the oxygen concentration in the low-resistance region 21 exceeds 30%, the resistance increases.

Alternatively, the low-resistance region 21 is made to have a low resistance by including aluminum as a dopant. It is desirable that the concentration of the aluminum included in the low-resistance region 21 be higher than that of the channel region 20A.

Incidentally, in each of the source region 20S and the drain region 20D, any region except the low-resistance region 21 is made of an oxide semiconductor like the channel region 20A. The depth of the low-resistance region 21 will be described later.

The gate insulating film 30 has, for example, a thickness of around 300 nm, and is configured by employing a single-layer film or a laminated film made of a silicon oxide film, a silicon nitride film, a silicon oxynitride film, an aluminum oxide film, or the like. In particular, the silicon nitride film or the aluminum oxide film is preferable because it is hard for these films to cause reduction of the oxide semiconductor film 20.

The gate electrode 40 has a role to apply a gate voltage to the thin film transistor 1 and control an electron density in the oxide semiconductor film 20 with this gate voltage. The gate electrode 40 is provided in a selective region on the substrate 11, and has, for example, a thickness of 10 nm to 500 nm, specifically, around 200 nm, and is made of molybdenum (Mo). It is desirable that the gate electrode 40 be of low resistance and therefore, as a material of the gate electrode 40, it is preferable to use, for example, a low resistance metal such as aluminum (Al) or copper (Cu). In addition, a laminated film formed by combining a low-resistance layer made of aluminum (Al) or copper (Cu) with a barrier layer made of titanium (Ti) or molybdenum (Mo) is also preferable. This is because a reduction in the resistance of the gate electrode 40 is possible.

The interlayer insulating film 50 is provided to be in contact with the oxide semiconductor film 20 and includes an organic resin film 51. This makes it possible for this thin film transistor 1 to suppress a failure due to the interlayer insulating film 50, and improve reliability of the thin film transistor 1 having the self-alignment structure.

The organic resin film 51 has, for example, a thickness of around 2 to 3 μm, and is an organic resin film made of imide resin such as polyimide, acrylic resin, or novolak resin. Because the interlayer insulating film 50 includes the organic resin film 51, the interlayer insulating film 50 is allowed to have a film thickness of around 2 μm. Therefore, a step of the gate insulating film 30 and the gate electrode 40 may be surely covered with the interlayer insulating film 50 that is sufficiently thick, and a failure due to the interlayer insulating film 50 such as disconnection of the source electrode 60S and the drain electrode 60D or a short may be reduced. In addition, a wiring capacity formed by metal wirings may be reduced, which makes it possible to sufficiently deal with an increase in the size as well as an increase in the frame rate of a liquid crystal or an organic EL display.

Further, it is preferable that the interlayer insulating film 50 have a layered structure including the organic resin film 51 and a first inorganic insulating film 52. Electrical properties of the oxide semiconductor film 20 easily change due to oxygen and water. However, thanks to the first inorganic insulating film 52 having a high barrier property against oxygen, water, and the like, mixing and diffusion of water into the oxide semiconductor film 20 may be suppressed and thereby, the reliability of the thin film transistor 1 may be improved.

It is preferable that the interlayer insulating film 50 have the first inorganic insulating film 52 and the organic resin film 51 laminated in this order from the side where the oxide semiconductor film 20 is provided. This is because since protection near the oxide semiconductor film 20 is enabled by the first inorganic insulating film 52 having the high barrier property, a higher effect is achieved.

Preferably, the first inorganic insulating film 52 is made of, for example, an aluminum oxide film, an titanium oxide film, or an indium oxide film. The first inorganic insulating film 52 made of titanium oxide, aluminum oxide, or indium oxide has an excellent barrier property against outside air. Therefore, the first inorganic insulating film 52 makes it possible to reduce the influence of oxygen and water causing a change in the electrical properties of the oxide semiconductor film 20, and stabilize the electrical properties of the thin film transistor 1. The thickness of the first inorganic insulating film 52 is, for example, 20 nm or less.

The source electrode 60S and the drain electrode 60D are connected to the low-resistance region 21 of the source region 20S and the low-resistance region 21 of the drain region 20D, respectively, via connection holes 50A provided in the interlayer insulating film 50. For example, the source electrode 60S and the drain electrode 60D each have a thickness of around 200 nm, and is made of molybdenum (Mo). Further, it is preferable that, like the gate electrode 40, each of the source electrode 60S and the drain electrode 60D be formed of a low-resistance metal wiring made of aluminum (Al), copper (Cu), or the like. Furthermore, a laminated film formed by combining a low-resistance layer made of aluminum (Al) or copper (Cu) with a barrier layer made of titanium (Ti) or molybdenum (Mo) is also preferable. Use of such a laminated film allows driving with a small wiring delay.

In addition, it is desirable that each of the source electrode 60S and the drain electrode 60D be provided to avoid a region immediately above the gate electrode 40.

This is because it is possible to reduce parasitic capacitance formed in a cross region between the gate electrode 40 and the source electrode 60S as well as the drain electrode 60D.

This thin film transistor 1 may be produced as follows, for example.

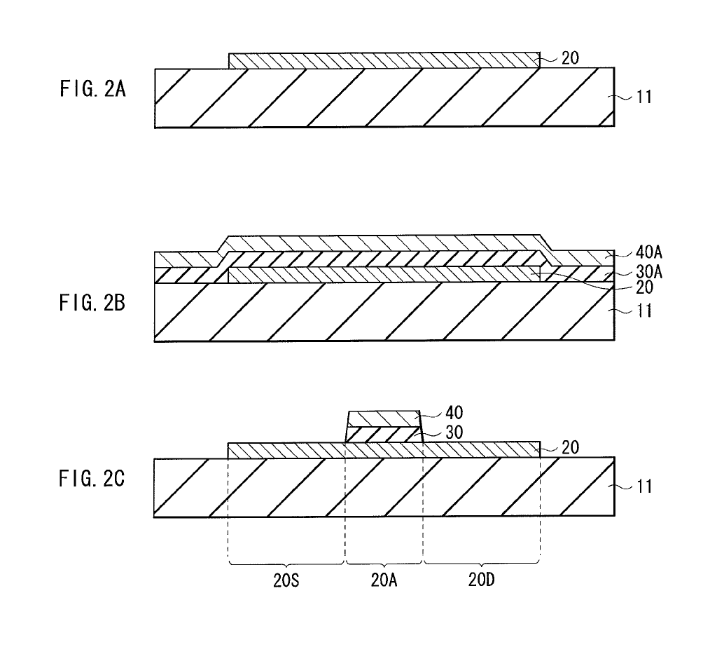

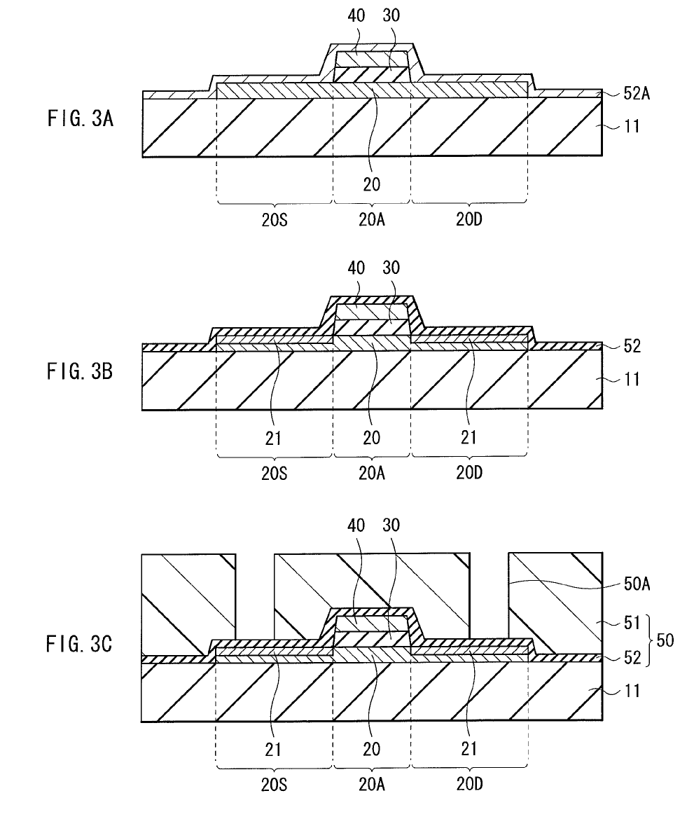

FIGS. 2A to 2C and FIGS. 3A to 3C illustrate a method of producing the thin film transistor 1, in a process order. First, on the entire surface of the substrate 1, the oxide semiconductor film 20 made of the above-described material is formed by, for example, a sputtering method, to have a thickness of around 50 nm. At this time, as a target, a ceramic target of the same composition as that of the oxide semiconductor film 20 to be formed is used. In addition, a carrier concentration in the oxide semiconductor film 20 largely depends on an oxygen partial pressure in the sputtering and thus, the oxygen partial pressure is controlled to obtain a desired transistor characteristic.

Subsequently, as illustrated in FIG. 2A, the oxide semiconductor film 20 is formed to have an island shape including the channel region 20A, the source region 20S on one side, and the drain region 20D on the other side, by photolithography and etching, for example. At this time, it is desirable to process by wet etching using a mixture of phosphoric acid, nitric acid, and acetic acid. The mixture of phosphoric acid, nitric acid, and acetic acid may sufficiently increase a selection ratio to a substrate, enabling relatively easy processing.

Subsequently, as illustrated in FIG. 2B, on the entire surfaces of the substrate 11 and the oxide semiconductor film 20, a gate insulating material film 30A such as a silicon nitride film or an aluminum oxide film is formed to have a thickness of around 300 nm, by, for example, a plasma CVD (Chemical Vapor Deposition) method or the like. The silicon nitride film may be formed by a reactive sputtering method, other than the plasma CVD method. Further, the aluminum oxide film may be formed by a reactive sputtering method, a CVD method, or atomic layer deposition.

Subsequently, as also illustrated in FIG. 2B, on the entire surface of the gate insulating material film 30A, a gate-electrode material film 40A that is a single-layer film or a laminated film made of molybdenum (Mo), titanium (Ti), aluminum (Al), and the like is formed to have a thickness of around 200 nm, by a sputtering method, for example.

After the gate-electrode material film 40A is formed, as illustrated in FIG. 2C, the gate-electrode material film 40A is formed into a desired shape by, for example, photolithography and etching, and thereby, the gate electrode 40 is formed on the channel region 20A of the oxide semiconductor film 20.

Subsequently, as also illustrated in FIG. 2C, the gate insulating film 30 is formed by etching the gate insulating material film 30A, using the gate electrode 40 as a mask. At this time, in a case where the oxide semiconductor film 20 is made of a crystallized material such as ZnO, IZO, and IGO, it is possible to carry out processing easily, while maintaining a large etching selection ratio by using a chemical solution such as hydrofluoric acid, at the time of etching the gate insulating material film 30A. As a result, on the channel region 20A of the oxide semiconductor film 20, the gate insulating film 30 and the gate electrode 40 are formed in this order to be identical in shape.

After the gate insulating film 30 and the gate electrode 40 are formed, as illustrated in FIG. 3A, on the surfaces of the oxide semiconductor film 20, the gate insulating film 30, and the gate electrode 40, a metal film 52A made of a metal such as titanium (Ti), aluminum (Al), or indium (In) which reacts with oxygen at a relatively low temperature is formed by, for example, a sputtering method. The metal film 52A is formed to have a thickness of, for example, 10 nm or less, specifically, a thickness of 5 nm or more and 10 nm or less.

After the metal film 52A is formed, a heat treatment is performed. As a result, as illustrated in FIG. 3B, the metal film 52A is oxidized, and thereby the first inorganic insulating film 52 is formed. In the oxidization reaction of this metal film 52A, a part of oxygen included in the source region 20S and the drain region 20D is used. Therefore, as the oxidization of the metal film 52A progresses, the oxygen concentration in each of the source region 20S and the drain region 20D decreases, starting from the top surface of each of the source region 20S and the drain region 20D, the top surface contacting the metal film 52A. As a result, the low-resistance regions 21 where the oxygen concentration is lower than that of the channel region 20A are each formed in the part of each of the source region 20S and the drain region 20D in the depth direction from the top surface.

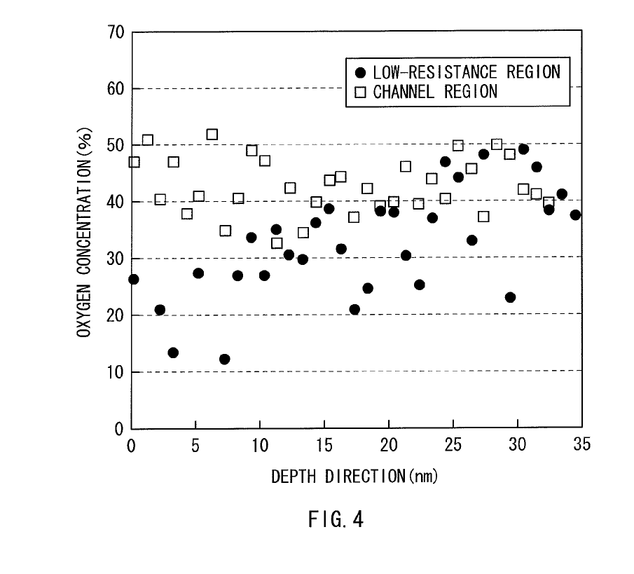

FIG. 4 illustrates a result of subjecting the metal film 52A to the heat treatment and then examining a dependence of the oxygen concentration in the channel region 20A and the source region 20S as well as the drain region 20D upon the depth direction, by using an EDX (Energy-Dispersive X-ray spectroscopy) method. At this time, the material of the oxide semiconductor film 20 is IGZO, the metal film 52A is an aluminum film having a thickness of 5 nm, and the heat treatment is performed through annealing at 300° C.

As illustrated in FIG. 4, it is apparent that the oxygen concentration in the source region 20S and the drain region 20D is lower than the oxygen concentration in the channel region 20A, across the whole in the depth direction. In particular, in a region at a depth of 10 nm or less, a difference between the oxygen concentration of the channel region 20A and the oxygen concentration in the source region 20S and the drain region 20D is clear. In other words, it is found that the low-resistance region 21 is a part of each of the source region 20S and the drain region 20D in the depth direction from the top surface, i.e., a region at the depth of 10 nm or less.

Further, in a case where aluminum is used as a material of the metal film 52A to form the low-resistance region 21, the aluminum diffuses in the source region 20S and the drain region 20D, from the top surface contacting the metal film 52A of the source region 20S and the drain region 20D, accompanying the heat treatment of the metal film 52A. As a result, the low-resistance region 21 that includes the aluminum as a dopant is formed in the part of each of the source region 20S and the drain region 20D in the depth direction from the top surface. The concentration of the aluminum included in this low-resistance region 21 is higher than that of the channel region 20A. In other words, the aluminum included in the low-resistance region 21 serves also as the dopant, thereby reducing the resistance of the source region 20S and the drain region 20D.

As the heat treatment of the metal film 52A, as mentioned above, it is preferable to perform, for example, the annealing at 300° C. At this time, the annealing is performed in an atmosphere of oxidized gas including oxygen and the like, and thereby the oxygen concentration of the low-resistance region 21 may be prevented from becoming too low, and sufficient oxygen may be supplied to the oxide semiconductor film 20 that becomes a channel. Therefore, it is possible to reduce an annealing process to be performed as a post process, thereby simplifying the process.

Furthermore, for example, by setting the temperature of the substrate 11 to a relatively high temperature of around 200° C. in the process of forming the metal film 52A illustrated in FIG. 3A, the low-resistance region 21 may be formed without performing the heat treatment illustrated in FIG. 3B. In this case, the carrier concentration of the oxide semiconductor film 20 becoming the channel may be reduced to a desirable level for serving as a transistor.

As described above, it is desirable that the metal film 52A be formed to have a thickness of 10 nm or less. This is because when the thickness of the metal film 52A is 10 nm or less, the metal film 52A may be completely oxidized in oxygen plasma, by performing the annealing in the atmosphere of oxidized gas. Therefore, a process employing etching to remove the metal film 52A not completely oxidized may become unnecessary, and thereby the production process may be simplified. When the metal film 52A is formed to have the thickness 10 nm or less, the thickness of the first inorganic insulating film 52 becomes 20 nm or less as a result.

At this time, as a method of oxidizing the metal film 52A, other than the heat treatment, oxidization in a water-vapor atmosphere or plasma oxidization may be employed to accelerate the oxidization. In the plasma oxidization, for example, it is desirable to perform processing by setting the temperature of the substrate 11 to around 200° C. to 400° C., and producing plasma in an atmosphere of gas including oxygen, such as oxygen, nitrous oxide, or the like. This is because this processing makes it possible to form the first inorganic insulating film 52 having the excellent barrier property against the outside air as described above.

It is to be noted that the first inorganic insulating film 52 is also formed on the gate insulating film 30, the gate electrode 40, or the like, other than the source region 20S and the drain region 20D of the oxide semiconductor film 20. However, even if the first inorganic insulating film 52 is left without being removed by etching, this will not cause a leakage current.

Here, in an application of a liquid crystal display, an organic EL display, when it is desirable to cause light to pass through in a direction of the substrate 11 of the thin film transistor 1, or the like, if the first inorganic insulating film 52 is allowed to remain, there is a case in which transmissivity of the first inorganic insulating film 52 is low. Therefore, in this case, luminance is decreased, and thereby display quality as a display is reduced. In this case, it is possible to remove a region of the first inorganic insulating film 52 except a part contacting the oxide semiconductor film 20, by performing a process of photolithography and etching. Undergoing such a process makes it possible to improve the transmissivity of the display and therefore, the technique of the present embodiment may be applied to the case in which the light passes through the substrate 11 of the thin film transistor 1 in the application of the liquid crystal display, organic EL, or the like.

After the low-resistance region 21 is formed, as illustrated in FIG. 3C, an organic resin made of the material described above is applied onto the first inorganic insulating film 52 to have the above-described thickness, by using a spin coater or a slit coater, and then, exposure and development are performed to form a desired pattern. Subsequently, annealing at temperatures of, for example, around 200° C. to 300° C. is performed and thereby, as illustrated in FIG. 3C, the organic resin film 51 having the connection holes 50A is formed.

The interlayer insulating film 50 is thus formed to include the organic resin film 51, and thereby the interlayer insulating film 50 may be formed without going through a vacuum process such as a CVD process. Therefore, it is possible to form the thin film transistor 1 in a state of suppressing an influence of reduction reaction caused by factors such as desorption of oxygen in the oxide semiconductor film 20, hydrogen produced in the CVD process, and the like. As a result, the thin film transistor 1 with high electrical stability and reliability may be formed.

Subsequently, as illustrated in FIG. 1, the connection holes 50A are formed in the first inorganic insulating film 52 of the interlayer insulating film 50, by photolithography and etching, for example. Afterwards, on the interlayer insulating film 50, a molybdenum (Mo) film is formed by sputtering to have a thickness of 200 nm, and then is formed into a predetermined shape by photolithography and etching, for example. As a result, as illustrated in FIG. 1, the source electrode 60S and the drain electrode 60D are connected to the low-resistance regions 21 of the source region 20S and the drain region 20D, via the connection holes 50A. This completes the thin film transistor 1 illustrated in FIG. 1.

In this thin film transistor 1, when a voltage (gate voltage) equal to or higher than a predetermined threshold voltage is applied to the gate electrode 40 through a wiring layer not illustrated, a current (a drain current) is produced in the channel region 20A of the oxide semiconductor film 20. Here, the interlayer insulating film 50 includes the organic resin film 51 and thus, the thickness of the interlayer insulating film 50 may be increased, and a step of the gate insulating film 30 and the gate electrode 40 is reliably covered with the interlayer insulating film 50 that is sufficiently thick. Therefore, a failure due to the interlayer insulating film 50 such as disconnection of the source electrode 60S and the drain electrode 60D or a short circuit is suppressed.

Further, in at least a part of each of the source region 20S and the drain region 20D of the oxide semiconductor film 20, in the depth direction from the top surface, the low-resistance region 21 having the oxygen concentration lower than that of the channel region 20A and/or including a large amount of aluminum as a donor and therefore, the device characteristic is stable.

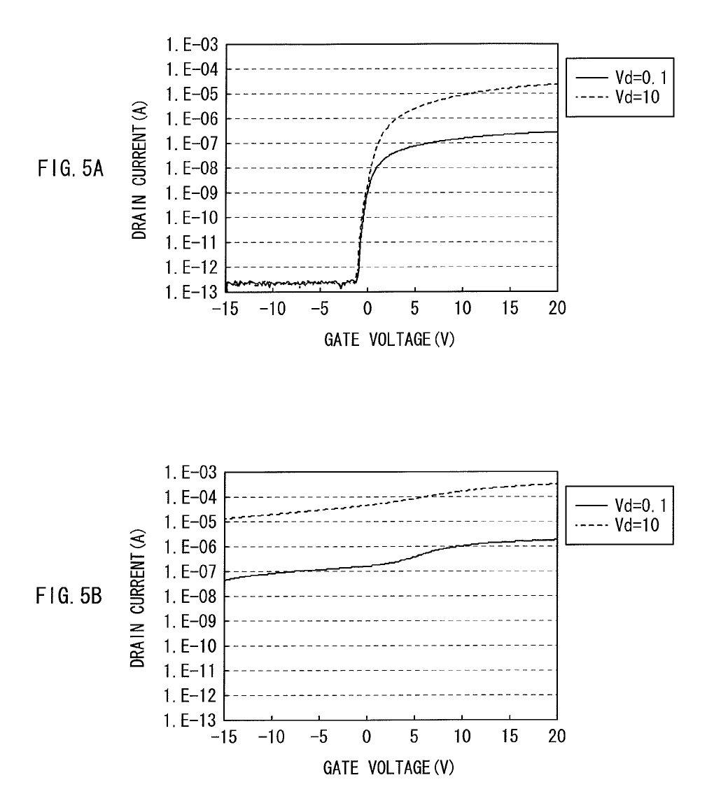

FIG. 5A illustrates a result of actually producing the thin film transistor 1 in which the organic resin film 51 is included in the interlayer insulating film 50 by the production process described above, and examining transistor characteristics. At this time, an aluminum oxide film having a thickness of 10 nm was formed as the first inorganic insulating film 52, and a polyimide film having a thickness of 3 μm was formed as the organic resin film 51. Further, in a final process of producing the thin film transistor, annealing at 300° C. was performed for one hour in an atmosphere of gas including nitrogen and oxygen with an oxygen concentration of 40%.

On the other hand, a thin film transistor is produced in a manner similar to the case in FIG. 5A, except that a silicon oxide film having a thickness of 200 nm was formed as an interlayer insulating film by a plasma CVD method, and transistor characteristics were examined. In a final process of producing the thin film transistor, annealing at 300° C. was performed for one hour in an atmosphere of gas including nitrogen and oxygen with an oxygen concentration of 40%, in a manner similar to the case in FIG. 5A. An obtained result is illustrated in FIG. 5B.

As depicted in FIG. 5A, as for the thin film transistor 1 in which the first inorganic insulating film 52 made of the aluminum oxide film and the organic resin film 51 made of the polyimide film are formed as the interlayer insulating film 50, there is obtained excellent characteristics in which an OFF-state current is suppressed to a sufficiently low level. In contrast, in the case in which the silicon nitride film is used as the interlayer insulating film, as illustrated in FIG. 5B, an OFF state is not achieved even when a negative voltage is applied to a gate electrode.

A conceivable reason for this is that in the thin film transistor 1 having the layered structure of the first inorganic insulating film 52 and the organic resin film 51 as the interlayer insulating film 50, the step formed after processing of the gate electrode 40 and the gate insulating film 30 is covered by the interlayer insulating film 50 that is sufficiently thick, and failures due to the interlayer insulating film 50, such as disconnection of the source electrode 60S and the drain electrode 60D or a short circuit, are reduced. Further, another conceivable reason is that oxygen diffusion is promoted by the annealing process in the atmosphere of oxidized gas in the final process of producing the thin film transistor, thereby making it possible to supply a sufficient amount of oxygen into the oxide semiconductor film 20.

On the other hand, in the case in which the silicon oxide film is used as the interlayer insulating film, it is conceivable that the thickness of the interlayer insulating film is small and thus, the occurrence of failures is not sufficiently suppressed, and moreover, it is difficult to supply sufficient oxygen in the annealing process and therefore, there is obtained TFT characteristics not achieving an OFF state. Even in this case, by setting the time of annealing in the atmosphere of oxidized gas to about ten hours, the TFT characteristic achieving the OFF state is obtained, but this increases the production time and thus is undesirable.

In other words, it is found that because the first inorganic insulating film 52 made of the aluminum oxide film and the organic resin film 51 made of the polyimide film are formed as the interlayer insulating film 50, there is realized the thin film transistor 1 reducing parasitic capacitance through the self-alignment structure, as well as having excellent device characteristics and high reliability.

In this way, with the thin film transistor 1 of the present embodiment, since the interlayer insulating film 50 includes the organic resin film 51, it is possible to suppress a failure caused by the interlayer insulating film 50 such as disconnection of the source electrode 60S and the drain electrode 60D or a short circuit, and to improve the device characteristics and the reliability of the thin film transistor 1 of top-gate type having the self-alignment structure. Therefore, when a display employing an active drive system is configured by using this thin film transistor 1, high-quality display is enabled by the thin film transistor 1 having the self-alignment structure with small parasitic capacitance, and also having excellent device characteristics as well as high reliability. Accordingly, it is possible to support a larger screen size, higher definition, and a higher frame rate. In addition, a layout with small retention capacitor may be used, and the proportion of wirings in a pixel layout may be reduced. Therefore, the probability of occurrence of a defect by a short circuit between wirings may be reduced, and production yield may be improved.

### (Modification 1)

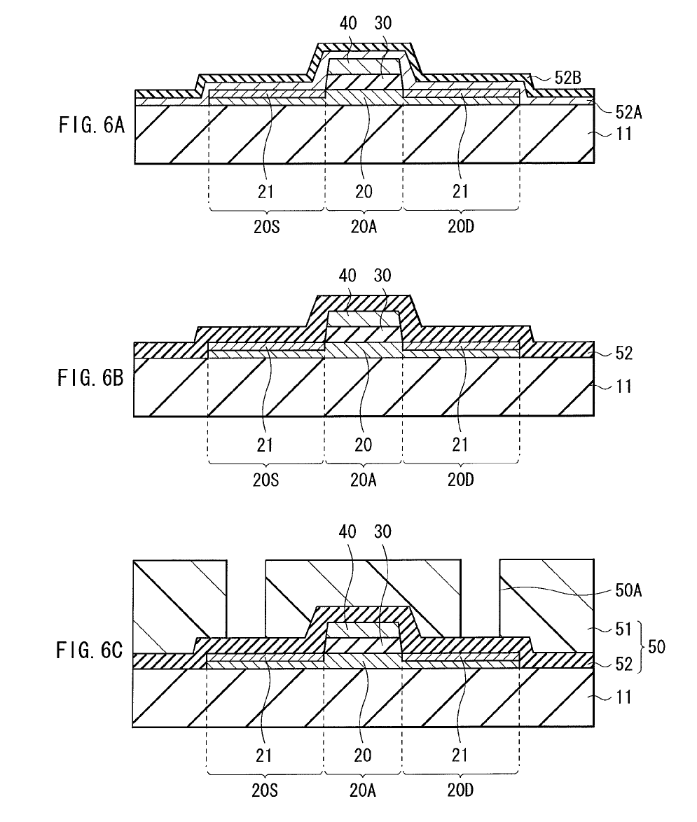

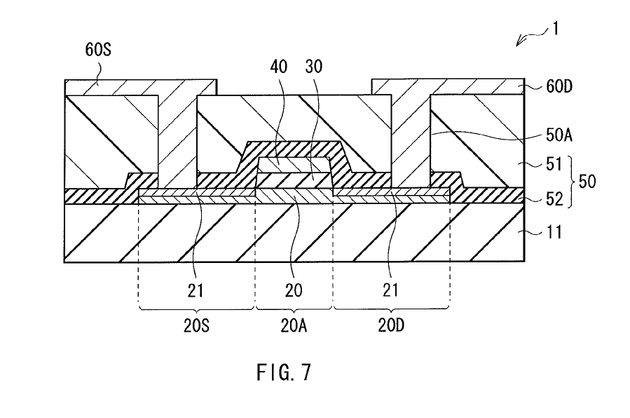

FIGS. 6A to 6C and FIG. 7 illustrate a method of producing a thin film transistor 1 according to the modification 1 of the present disclosure, in process order. This method is different from the method in the first embodiment, in that a first inorganic insulating film 52 is formed by laminating a metal film 52A and a metal oxide film 52B and oxidizing the metal film 52A. It is to be noted that a part overlapping the production process of the first embodiment will be described with reference to FIGS. 2A to 2C.

First, in a manner similar to the first embodiment, through the process illustrated in FIG. 2A to FIG. 2C, an oxide semiconductor film 20, a gate insulating film 30 and a gate electrode 40 are formed on a substrate 11.

Subsequently, as illustrated in FIG. 6A, on surfaces of the oxide semiconductor film 20, the gate insulating film 30 and the gate electrode 40, the metal film 52A made of metal which reacts with oxygen at a relatively low temperature such as titanium (Ti), aluminum (Al), or indium (In) is formed by, for example, a sputtering method, to have a thickness of 10 nm or less, specifically, a thickness of 5 nm or more and 10 nm or less.

Subsequently, as also illustrated in FIG. 6A, in a chamber of a sputtering system (not illustrated), the metal oxide film 52B that is an aluminum oxide film, a titanium oxide film, or an indium oxide film is formed on the metal film 52A to have a thickness of, for example, 10 nm to 50 nm both inclusive, continuously from the metal film 52A.

After the metal film 52A and the metal oxide film 52B are formed, a heat treatment similar to that in the first embodiment is performed. As a result, as illustrated in FIG. 6B, the metal film 52A is oxidized and thereby the first inorganic insulating film 52 is formed. The thickness of the first inorganic insulating film 52 is the sum of the thickness after the oxidization of the metal film 52A (20 nm or less when the metal film 52A is formed to have a thickness of 10 nm or less) and the thickness of the metal oxide film 52B. Therefore, the thickness of the first inorganic insulating film 52 may be increased, making it possible to improve reliability of the thin film transistor 1.

Further, concurrently with formation of the first inorganic insulating film 52, a low-resistance region 21 where an oxygen concentration is lower than that of a channel region 20A is formed in a part of each of a source region 20S and a drain region 20D in a depth direction from a top surface, in a manner similar to that in the first embodiment.

As the heat treatment of the metal film 52A, like the first embodiment, it is desirable to perform annealing at a temperature of around 300° C. At this time, the annealing is performed in an atmosphere of oxidized gas including oxygen and the like, and thereby the oxygen concentration of the low-resistance region 21 may be prevented from becoming too low and sufficient oxygen may be supplied to the oxide semiconductor film 20 that becomes a channel. Therefore, it is possible to reduce an annealing process to be performed as a post process, thereby simplifying the process.

Furthermore, for example, by setting the temperature of the substrate 11 to a relatively high temperature of around 200° C. in the process of forming the metal film 52A illustrated in FIG. 6A, the low-resistance region 21 may be formed without performing the heat treatment illustrated in FIG. 6B. In this case, a carrier concentration of the oxide semiconductor film 20 becoming the channel may be reduced to a desired level for serving as a transistor.

As described above, it is desirable that the metal film 52A be formed to have a thickness of 10 nm or less. This is because when the thickness of the metal film 52A is 10 nm or less, the metal film 52A and the metal oxide film 52B are continuously formed, and thereby the metal film 52A may be completely oxidized in oxygen plasma. Therefore, a process employing etching to remove the metal film 52A not completely oxidized may become unnecessary, and thereby the production process may be simplified.

At this time, as a method of oxidizing the metal film 52A, other than the heat treatment, oxidization in a water-vapor atmosphere or plasma oxidization may be employed to accelerate the oxidization, like the first embodiment. In particular, as will be described later for the modification 2, the plasma oxidization may be performed immediately before the first inorganic insulating film 52 made of a silicon nitride film or the like is formed by a plasma CVD method in a post process, which has such an advantage that a process may not be particularly added. In the plasma oxidization, for example, it is desirable to perform processing by setting the temperature of the substrate 11 to around 200° C. to 400° C., and producing plasma in an atmosphere of gas including oxygen, such as oxygen, nitrous oxide, or the like. This is because this processing makes it possible to form the first inorganic insulating film 52 having the excellent barrier property against the outside air as described above.

It is to be noted that the first inorganic insulating film 52 is also formed on the gate insulating film 30, the gate electrode 40, or the like, other than the source region 20S and the drain region 20D of the oxide semiconductor film 20. However, even if the first inorganic insulating film 52 is left without being removed by etching, this will not cause a leakage current.

After the low-resistance region 21 is formed, as illustrated in FIG. 6C, an organic resin film 51 having connection holes 50A is formed on the first inorganic insulating film 52, in a manner similar to that in the first embodiment.

Subsequently, as illustrated in FIG. 7, the connection holes 50A are formed in the first inorganic insulating film 52 of the interlayer insulating film 50 in a manner similar to that in the first embodiment, and then, a source electrode 60S and a drain electrode 60D are connected to the low-resistance regions 21 of the source region 20S and the drain region 20D via the connection holes 50A. This completes the thin film transistor 1.

In the modification 1, in addition to the effect in the first embodiment, it is possible to increase the thickness of the first inorganic insulating film 52, since the first inorganic insulating film 52 is formed by laminating the metal film 52A and the metal oxide film 52B and oxidizing the metal film 52A. Therefore, it is possible to improve the reliability of the thin film transistor 1 further.

### (Modification 2)

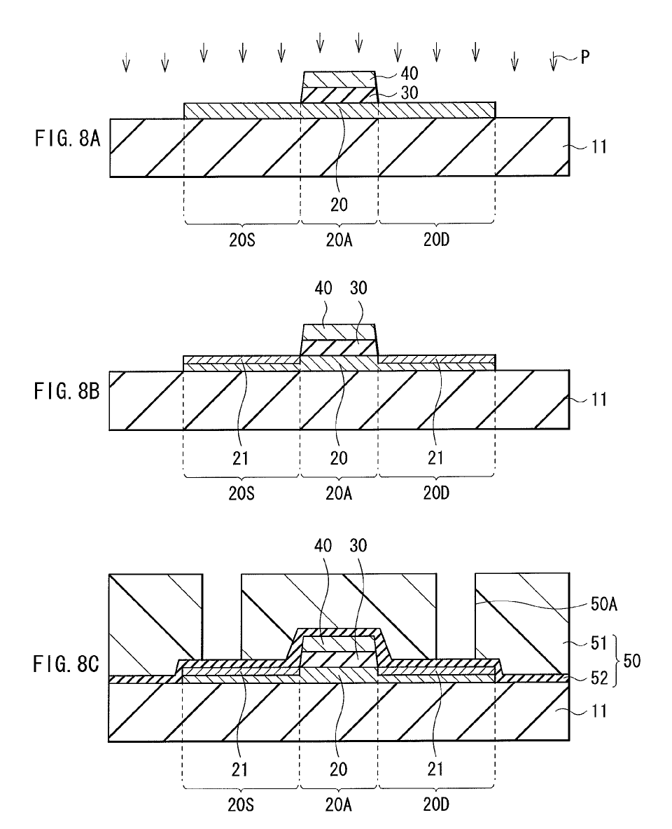

FIGS. 8A to 8C illustrate a method of producing a thin film transistor 1 according to the modification 2 of the present disclosure, in process order. This method is different from the method of the first embodiment described above, in that a low-resistance region 21 is formed by using plasma. It is to be noted that a part overlapping the production process in the first embodiment will be described with reference to FIG. 1 and FIGS. 2A to 2C.

First, in a manner similar to the first embodiment, an oxide semiconductor film 20, a gate insulating film 30 and a gate electrode 40 are formed on a substrate 11 through the process illustrated in FIG. 2A to FIG. 2C.

Subsequently, as illustrated in FIG. 8A, in a plasma CVD device (not illustrated), plasma P such as hydrogen, argon, or ammonia gas is produced, and a source region 20S and a drain region 20D of the oxide semiconductor film 20 are subjected to the plasma P. As a result, as illustrated in FIG. 8B, for example, hydrogen with an atomic concentration of around 1% is introduced into a part of each of the source region 20S and the drain region 20D in a depth direction from a top surface, and thereby a low-resistance region 21 is formed. It is to be noted that the low-resistance region 21 may be formed by ion doping or ion implantation, other than a plasma treatment including hydrogen gas by a plasma CVD method or the like.

Subsequently, as illustrated in FIG. 8C, a first inorganic insulating film 52 is formed on the oxide semiconductor film 20, the gate insulating film 30 and the gate electrode 40. As the first inorganic insulating film 52, it is desirable to form, for example, a silicon oxide film or an aluminum oxide film or a laminated film formed from these films, by a plasma CVD method, for example. This has such an advantage that the low-resistance region 21 may be formed by using the plasma P, immediately before the first inorganic insulating layer 52 is formed by the plasma CVD method and thus, a process may not be particularly added.

The silicon oxide film may be formed by the plasma CVD method. It is desirable that the aluminum oxide film be formed by a reactive sputtering method, targeting aluminum and using DC or AC power. This is because it is possible to form the film at a high speed. When, for example, the aluminum oxide film is formed by a sputtering method, the first inorganic insulating film 52 may be formed to have a thickness of, for example, 50 nm or less.

Next, as also illustrated in FIG. 8C, on the first inorganic insulating film 52, an organic resin film 51 having connection holes 50A is formed in a manner similar to the first embodiment.

Subsequently, as illustrated in FIG. 1, in a manner similar to the first embodiment, the connection holes 50A are formed in the first inorganic insulating film 52 of the interlayer insulating film 50, and a source electrode 60S and a drain electrode 60D are connected to the low-resistance regions 21 of the source region 20S and the drain region 20D, via the connection holes 50A. This completes the thin film transistor 1.

In the modification 2, the interlayer insulating film 50 includes the organic resin film 51 and thus, an effect similar to that of the first embodiment is obtained.

### (Modification 3)

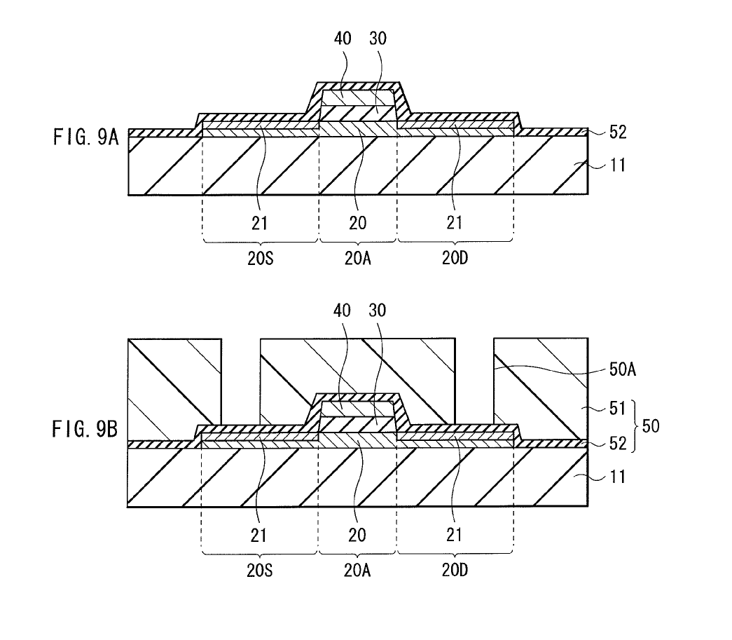

FIGS. 9A and 9B illustrate a method of producing a thin film transistor 1 according to the modification 3 of the present disclosure, in process order. This method is different from the method in the first embodiment described above, in that a low-resistance region 21 is formed by diffusion of hydrogen from a silicon nitride film. It is to be noted that a part overlapping the production process of the first embodiment will be described with reference to FIG. 1 and FIGS. 2A to 2C.

First, in a manner similar to the first embodiment, an oxide semiconductor film 20, a gate insulating film 30 and a gate electrode 40 are formed on a substrate 11, through the process illustrated in FIG. 2A to FIG. 2C.

Subsequently, as illustrated in FIG. 9A, on surfaces of the oxide semiconductor film 20, the gate insulating film 30 and the gate electrode 40, a first inorganic insulating film 52 made of an insulating film containing a large amount of hydrogen in a film such as a silicon nitride film is formed by, for example, a plasma CVD method. At this time, hydrogen diffuses in a source region 20S and a drain region 20D from the first inorganic insulating film 52, and thereby the hydrogen having an atomic concentration of around 1% is introduced into a part of each of the source region 20S and the drain region 20D in a depth direction from a top surface and as a result, the low-resistance region 21 is formed.

Next, as illustrated in FIG. 9B, on the first inorganic insulating film 52, an organic resin film 51 having connection holes 50A is formed in a manner similar to the first embodiment.

Subsequently, as illustrated in FIG. 1, in a manner similar to the first embodiment, the connection holes 50A are formed in the first inorganic insulating film 52 of the interlayer insulating film 50, and a source electrode 60S and a drain electrode 60D are connected to the low-resistance regions 21 of the source region 20S and the drain region 20D, via the connection holes 50A. This completes the thin film transistor 1.

In the modification 3, the interlayer insulating film 50 includes the organic resin film 51 and thus, an effect similar to that of the first embodiment is obtained.

It is to be noted that in the modification 3, before the first inorganic insulating film 52 is formed, the low-resistance region 21 may be formed in a part of each of the source region 20S and the drain region 20D in a depth direction from a top surface, by subjecting the source region 20S and the drain region 20D of the oxide semiconductor film 20 to plasma P such as hydrogen, argon, or ammonia gas, through the process illustrated in FIG. 8A, in a manner similar to the modification 2.

### (Modification 4)

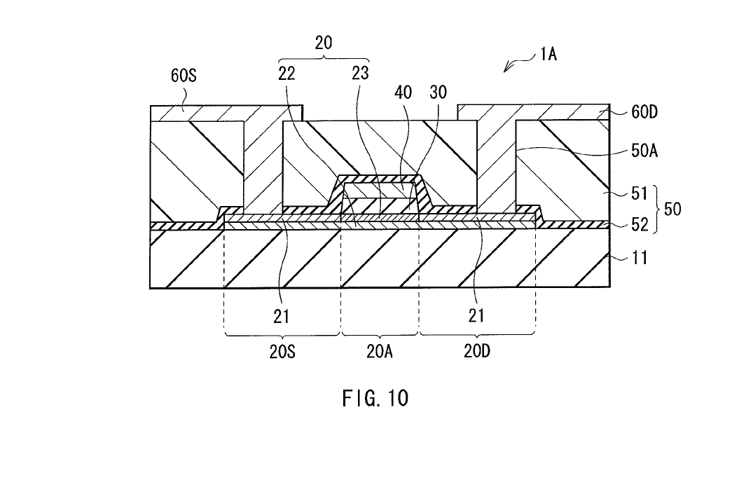

FIG. 10 illustrates a cross-sectional configuration of a thin film transistor 1A according to the modification 4 of the present disclosure. This thin film transistor 1A has a configuration similar to that of the thin film transistor 1 in the first embodiment, except an oxide semiconductor film 20 having a layered structure including an amorphous film 22 and a crystallized film 23, and has operation and effect similar to those of the first embodiment. Therefore, equivalent elements are provided with the same reference characters as those of the first embodiment, and will be described.

A substrate 11, a gate insulating film 30, a gate electrode 40, an interlayer insulating film 50, a source electrode 60S, and a drain electrode 60D are similar to those of the first embodiment.

The oxide semiconductor film 20 has the layered structure including the amorphous film 22 and the crystallized film 23. The source electrode 60S and the drain electrode 60D are provided in contact with the crystallized film 23. Specifically, the oxide semiconductor film 20 has a structure in which the amorphous film 22 and the crystallized film 23 are laminated in this order from a side where the substrate 11 is provided.

The amorphous film 22 has a function to serve as a channel of the thin film transistor 1A, and is provided on the substrate 11 side of the oxide semiconductor film 20. The amorphous film 22 has, for example, a thickness of around 10 to 50 nm, and is made of an oxide semiconductor in an amorphous state, such as IGZO. A TFT using an oxide semiconductor film in an amorphous state, which serves as a channel, provides an electrical property with excellent uniformity.

The crystallized film 23 is intended to secure an etching selection ratio to an upper layer in a production process, and disposed in the oxide semiconductor film 20 on the side where the source electrode 60S and the drain electrode 60D are provided. The crystallized film 23 has, for example, a thickness of around 10 to 50 nm, and is made of an oxide semiconductor in a crystallized state, such as zinc oxide, IZO, and IGO. The oxide semiconductor in the crystallized state is highly resistant to a chemical solution, and is allowed to suppress unintended etching of the oxide semiconductor film 20 at the time of etching the upper layer in the production process. Therefore, the thickness of the oxide semiconductor film 20 may not be increased, and excellent electrical properties are achieved.

It is to be noted that the thickness (a total thickness of the amorphous film 22 and the crystallized film 23) of the oxide semiconductor film 20 is desirably, for example, around 20 to 100 nm, considering an oxygen supply efficiency by annealing in the production process.

Like the first embodiment, each of a source region 20S and a drain region 20D of the oxide semiconductor film 20 has a low-resistance region 21 provided in a part in a depth direction from a top surface and having an oxygen concentration lower than that of a channel region 20A. Incidentally, FIG. 10 illustrates a case in which the depth of the low-resistance region 21 and the thickness of the crystallized film 23 are equal, but the low-resistance region 21 may be provided in a part in a depth direction from a top surface of the crystallized film 23. Further, the low-resistance region 21 may be provided over the whole in the depth direction from the top surface of the crystallized film 23, as well as in a part in a depth direction from an interface of the amorphous film 22 to the crystallized film 23.

This thin film transistor 1A may be produced as follows, for example.

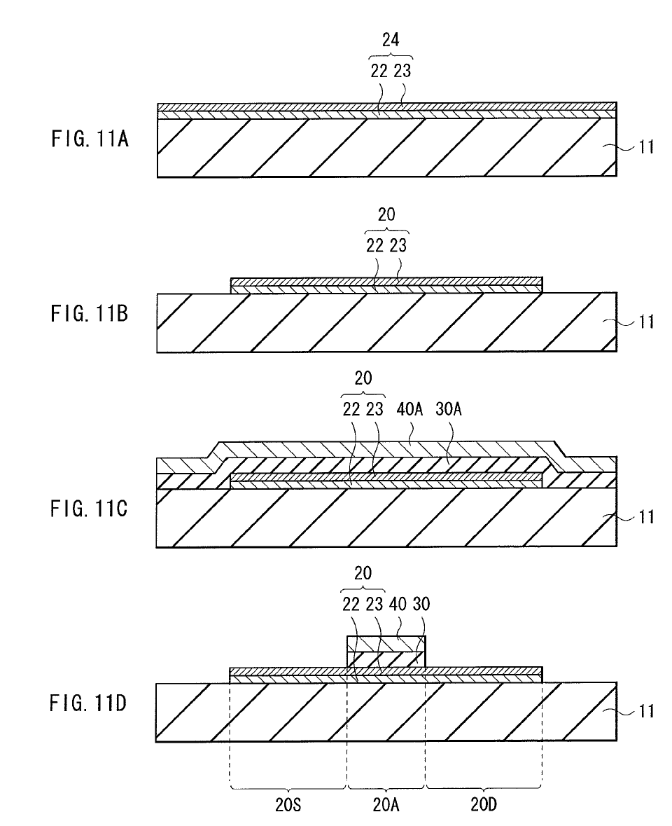

FIG. 11A to FIG. 13 illustrate a method of producing this thin film transistor 1A, in process order. First, as illustrated in FIG. 11A, on the substrate 11, the amorphous film 22 having the above-mentioned thickness and made of the above-mentioned material is formed by, for example, a sputtering method. Specifically, when, for example, the amorphous film 22 made of IGZO is formed, a DC sputtering method that targets ceramic of an IGZO film is used, and thereby an amorphous film 22 is formed through plasma arc by mixed gases of argon and oxygen. It is to be noted that oxygen is exhausted prior to the plasma arc until a degree of vacuum in a vacuum vessel (not illustrated) becomes 1×10⁻⁴Pa or less, and subsequently, the mixed gases of argon and oxygen is introduced.

At this time, a carrier concentration in the amorphous film 22 becoming the channel may be controlled by changing a flow ratio to argon and oxygen in oxide formation.

Next, as also illustrated in FIG. 11A, the crystallized film 23 having the above-mentioned thickness and made of the above-mentioned material is formed by, for example, a sputtering method. Specifically, when, for example, the crystallized film 23 made of IZO is formed, a DC sputtering method targeting ceramic of an IZO film is used. In this way, a laminated film 24 of the amorphous film 22 and the crystallized film 23 is formed.

Subsequently, as illustrated in FIG. 11B, the laminated film 24 is formed into a predetermined shape, e.g., an island shape allowed to include the gate electrode 40 and its neighborhood by, for example, photolithography and etching. As a result, the oxide semiconductor film 20 having the layered structure of the amorphous film 22 and the crystallized film 23 is formed.

Subsequently, as illustrated in FIG. 11C, on the entire surfaces of the substrate 11 and the oxide semiconductor film 20, a gate insulating material film 30A and a gate-electrode material film 40A are formed in this order, in a manner similar to the first embodiment.

After the gate-electrode material film 40A is formed, as illustrated in FIG. 11D, in a manner similar to the first embodiment, the gate-electrode material film 40A is formed into a desired shape by, for example, photolithography and etching, and thereby the gate electrode 40 is formed on the channel region 20A of the oxide semiconductor film 20.

Subsequently, as also illustrated in FIG. 11D, in a manner similar to the first embodiment, the gate insulating film 30 is formed through etching of the gate insulating material film 30A by using the gate electrode 40 as a mask. At this time, since the oxide semiconductor film 20 has the structure in which the amorphous film 22 and the crystallized film 23 are laminated in this order from the substrate 11 side, it is possible to easily perform processing by maintaining a large etching selection ratio through the use of a chemical solution such as hydrofluoric acid at the time of etching the gate insulating material film 30A. As a result, on the channel region 20A of the oxide semiconductor film 20, the gate insulating film 30 and the gate electrode 40 identical in shape are formed in this order.

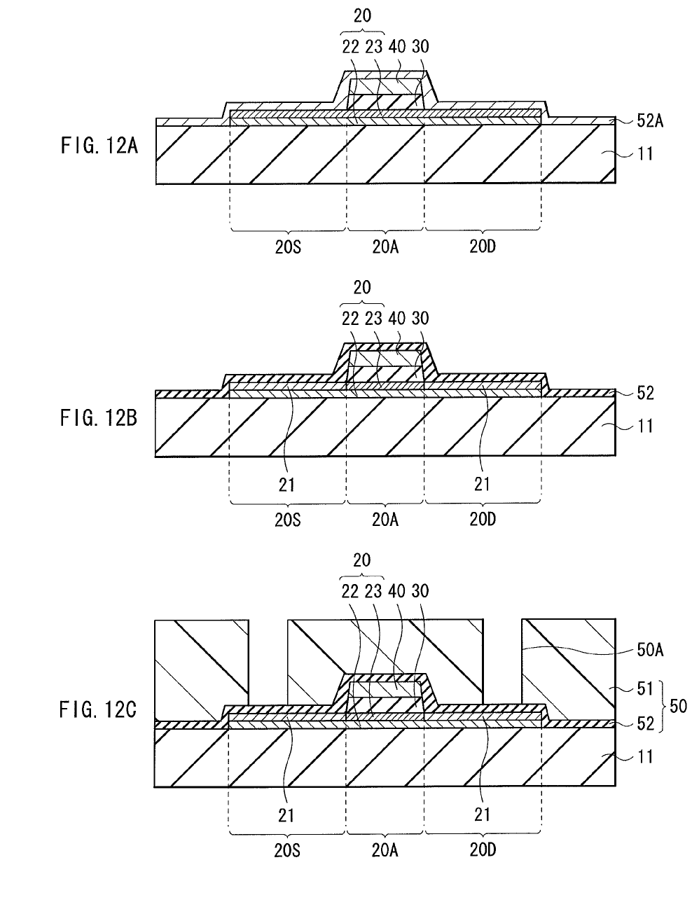

After the gate insulating film 30 and the gate electrode 40 are formed, as illustrated in FIG. 12A, in a manner similar to the first embodiment, on surfaces of the oxide semiconductor film 20, the gate insulating film 30, and the gate electrode 40, a metal film 52A made of a metal which reacts with oxygen at a relatively low temperature such as titanium (Ti), aluminum (Al), or indium (In) is formed by, for example, a sputtering method, to have a thickness of e.g. 10 nm or less, specifically, a thickness of 5 nm or more and 10 nm or less.

After the metal film 52A is formed, in a manner similar to the first embodiment, a heat treatment is performed, and thereby, as illustrated in FIG. 12B, the metal film 52A is oxidized and the first inorganic insulating film 52 is formed. At the same time, the low-resistance region 21 where the oxygen concentration is lower than that of the channel region 20A is formed in the part of each of the source region 20S and the drain region 20D in the depth direction from the top surface.

After the low-resistance region 21 is formed, as illustrated in FIG. 12C, in a manner similar to the first embodiment, an organic resin film 51 having connection holes 50A is formed on the first inorganic insulating film 52.

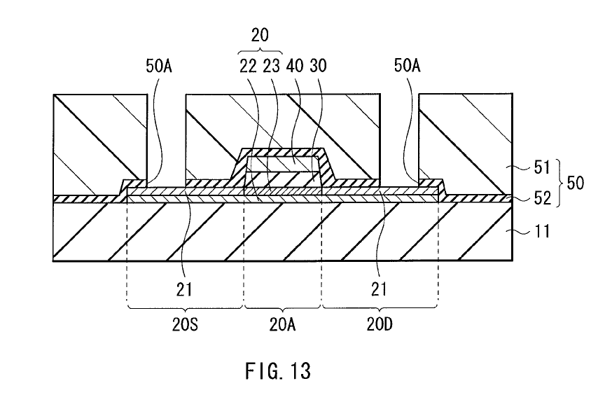

After the organic resin film 51 is formed, as illustrated in FIG. 13, the connection holes 50A are formed in the first inorganic insulating film 52 of this interlayer insulating film 50 by, for example, etching, and thereby the crystallized film 23 of the oxide semiconductor film 20 is exposed in each of the connection holes 50A. At this time, the first inorganic insulating film 52 of the interlayer insulating film 50 is provided on the crystallized film 23 and thus, an etching rate of the crystallized film 23 is sufficiently lower than that of the interlayer insulating film 50 and the gate insulating film 30, and a wet-etching selection ratio between the first inorganic insulating film 52 of the interlayer insulating film 50 and the oxide semiconductor film 20 increases. Therefore, it is possible to selectively etch the first inorganic insulating film 52 of the interlayer insulating film 50 while suppressing the etching of the oxide semiconductor film 20, thereby forming the connection holes 50A easily. Further, the first inorganic insulating film 52 made of an aluminum oxide film hard to process by dry etching also may be readily processed by wet etching.

Subsequently, as illustrated in FIG. 10, in a manner similar to the first embodiment, the source electrode 60S and the drain electrode 60D are formed and connected to the low-resistance regions 21 of the source region 20S and the drain region 20D, via the connection holes 50A. This completes the thin film transistor 1A illustrated in FIG. 10.

In this way, in the modification 4, the oxide semiconductor film 20 is formed to have the layered structure including the amorphous film 22 and the crystallized film 23 and thus, the amorphous film 22 makes it possible to obtain electrical properties with high uniformity. In addition, the source electrode 60S and the drain electrode 60D are provided to be in contact with the crystallized film 23 and thus, when etching the gate insulating film 30 or the first inorganic insulating film 52 in the production process, it is possible to prevent the oxide semiconductor film 20 from being etched. Therefore, the thickness of the oxide semiconductor film 20 may not be increased, making it possible to obtain excellent electrical properties while reducing the film formation time and the cost.

### (Modification 5)

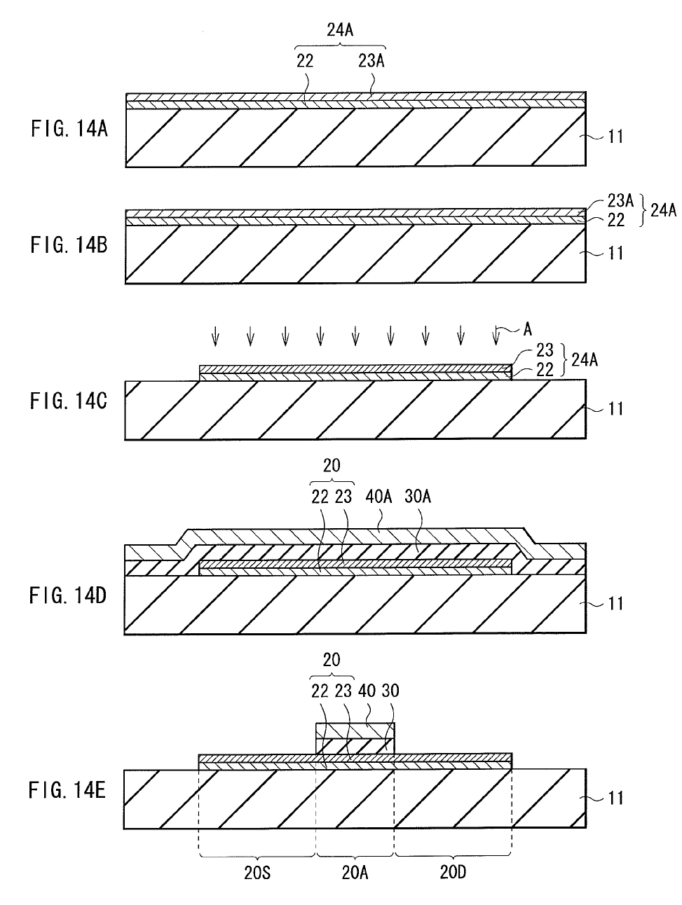

FIGS. 14A to 14E illustrate a method of producing a thin film transistor 1A according to the modification 5 of the present disclosure, in process order. This method is different from the method in the modification 4, in that after a laminated film including an amorphous film 22 and an amorphous film 23A is formed and this laminated film is processed by etching, the amorphous film 23A is annealed and thereby a crystallized film is formed. It is to be noted that a part overlapping the production process of the modification 4 will be described with reference to FIG. 11A to FIG. 13.

First, as illustrated in FIG. 14A, in a manner similar to the modification 4, the amorphous film 22 having the above-mentioned thickness and made of the above-mentioned material is formed on a substrate 11 by, for example, a sputtering method.

Subsequently, as also illustrated in FIG. 14A, the amorphous film 23A made of an oxide semiconductor having a melting point lower than that of the amorphous film 22 is formed by, for example, a sputtering method. Specifically, when, for example, the amorphous film 23A made of IZO is formed, a DC sputtering method targeting ceramic of an IZO film is used, and the amorphous film 23A made of IZO in an amorphous state is formed by controlling a sputtering condition. In this way, a laminated film 24A of the amorphous film 22 and the amorphous film 23A is formed.

After the laminated film 24A is formed, as illustrated in FIG. 14B, the laminated film 24A is formed into a predetermined shape, e.g., an island shape allowed to include a gate electrode 40 and its neighborhood by, for example, photolithography and etching. At this time, since the amorphous film 22 and the amorphous film 23A are both in the amorphous state, a reduction in cost may be achieved by performing wet etching using a mixture of phosphoric acid, nitric acid, and acetic acid.

After the laminated film 24A is formed, as illustrated in FIG. 14C, a crystallized film 23 is formed by subjecting the amorphous film 23A to, for example, annealing processing A at around 200° C. to 400° C. As a result, the oxide semiconductor film 20 having a layered structure including the amorphous film 22 and the crystallized film 23 is formed.

After the oxide semiconductor film 20 is formed, as illustrated in FIG. 14D, on the entire surfaces of the substrate 11 and the oxide semiconductor film 20, a gate insulating material film 30A and a gate-electrode material film 40A are formed in this order, in a manner similar to the modification 4.

After the gate-electrode material film 40A is formed, as illustrated in FIG. 14E, in a manner similar to the modification 4, the gate-electrode material film 40A is formed into a desired shape by, for example, photolithography and etching, and thereby the gate electrode 40 is formed on a channel region 20A of the oxide semiconductor film 20.

Subsequently, as also illustrated in FIG. 14E, in a manner similar to the modification 4, the gate insulating film 30 is formed by etching the gate insulating material film 30A, using the gate electrode 40 as a mask. At this time, the oxide semiconductor film 20 has the structure in which the amorphous film 22 and the crystallized film 23 are laminated in this order from the substrate 11 side and thus, processing may be easily carried out while maintaining a large etching selection ratio by using a chemical solution such as hydrofluoric acid, at the time of etching the gate insulating material film 30A. As a result, on the channel region 20A of the oxide semiconductor film 20, the gate insulating film 30 and the gate electrode 40 are formed in this order into the same shape.

After the gate insulating film 30 and the gate electrode 40 are formed, in a manner similar to the modification 4, through the process illustrated in FIG. 12A, on surfaces of the oxide semiconductor film 20, the gate insulating film 30, and the gate electrode 40, a metal film 52A made of a metal which reacts with oxygen at a relatively low temperature such as titanium (Ti), aluminum (Al), or indium (In) by, for example, a sputtering method, to have a thickness of e.g. 10 nm or less, specifically, a thickness of 5 nm or more and 10 nm or less.

After the metal film 52A is formed, a heat treatment is performed in a manner similar to the modification 4, through the process illustrated in FIG. 12B. As a result, the metal film 52A is oxidized and thereby a first inorganic insulating film 52 is formed. At the same time, the low-resistance region 21 where the oxygen concentration is lower than that of the channel region 20A is formed in a part of each of a source region 20S and a drain region 20D in a depth direction from a top surface.

After the low-resistance region 21 is formed, in a manner similar to the modification 4, an organic resin film 51 having connection holes 50A is formed on the first inorganic insulating film 52, through the process illustrated in FIG. 12C.

After the organic resin film 51 is formed, in a manner similar to the modification 4, through the process illustrated in FIG. 13, the connection holes 50A are formed in the first inorganic insulating film 52 of an interlayer insulating film 50 by, for example, etching, and thereby the crystallized film 23 of the oxide semiconductor film 20 is exposed in each of the connection holes 50A. At this time, the first inorganic insulating film 52 of the interlayer insulating film 50 is provided on the crystallized film 23 and thus, an etching rate of the crystallized film 23 is sufficiently lower than that of the interlayer insulating film 50 and the gate insulating film 30, and a wet-etching selection ratio between the first inorganic insulating film 52 of the interlayer insulating film 50 and the oxide semiconductor film 20 increases. Therefore, it is possible to selectively etch the first inorganic insulating film 52 of the interlayer insulating film 50 while suppressing the etching of the oxide semiconductor film 20, thereby forming the connection holes 50A easily. Further, the first inorganic insulating film 52 made of an aluminum oxide film hard to process by dry etching also may be readily processed by wet etching.

Subsequently, in a manner similar to the modification 4, as illustrated in FIG. 10, a source electrode 60S and a drain electrode 60D are formed and connected to the low-resistance regions 21 of the source region 20S and the drain region 20D, via the connection holes 50A. This completes a thin film transistor 1A illustrated in FIG. 10.

In this way, in the modification 5, the laminated film 24A, which includes the amorphous film 22 made of the oxide semiconductor and the amorphous film 23A made of the oxide semiconductor with the melting point lower than that of the amorphous film 22, is formed and then shaped by etching. Therefore, it is possible to easily form the laminated film 24A into a predetermined shape by low-cost wet etching. In addition, the crystallized film 23 is formed by subjecting the amorphous film 23A to the annealing processing, and thereby the oxide semiconductor film 20 having the layered structure including the amorphous film 22 and the crystallized film 23 is formed and thus, it is possible to increase the wet-etching selection ratio between the gate insulating film 30 or the first inorganic insulating film 52 and the oxide semiconductor film 20 in the production process. Therefore, like the modification 4, the thickness of the oxide semiconductor film 20 may not be increased, making it possible to obtain excellent electrical properties while reducing the film formation time and the cost.

### SECOND EMBODIMENT

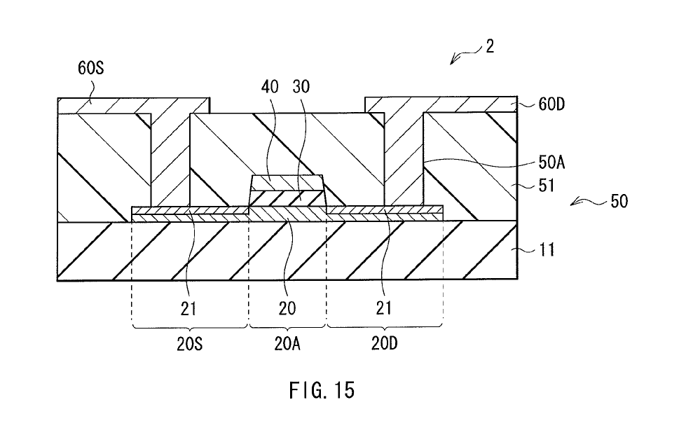

FIG. 15 illustrates a cross-sectional structure of a thin film transistor 2 according to the second embodiment of the present disclosure. This thin film transistor 2 has a configuration similar to that of the thin film transistor 1 in the first embodiment, except an interlayer insulating film 50 being formed of only an organic resin film 51, and provides operation and effect similar to those of the first embodiment.

This thin film transistor 2 may be produced as follows, for example. First, in a manner similar to the first embodiment, through the process illustrated in FIG. 2A to FIG. 3B, an oxide semiconductor film 20, a gate insulating film 30, a gate electrode 40, and a metal film 52A are formed on a substrate 11, and a low-resistance region 21 and a first inorganic insulating film 52 are formed by a heat treatment of the metal film 52A.

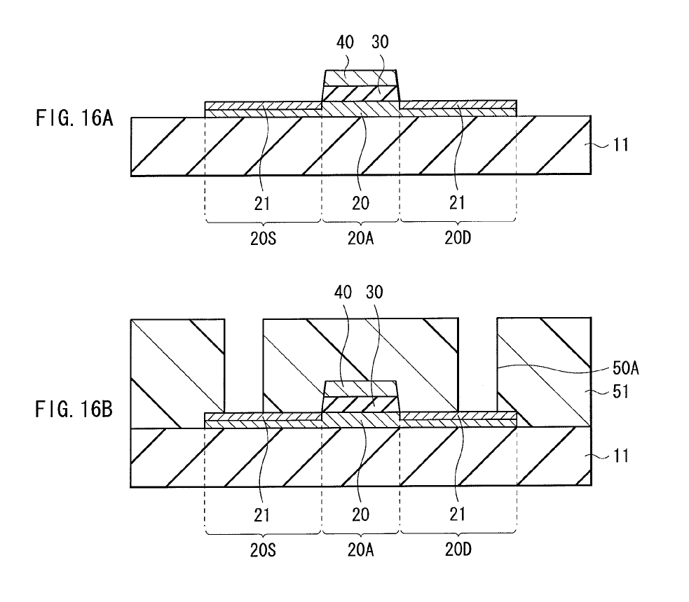

Subsequently, as illustrated in FIG. 16A, the first inorganic insulating film 52 is removed by etching. At this time, the first inorganic insulating film 52 and the metal film 52A not completely oxidized may be removed easily by dry etching using gas including chlorine and the like.

Subsequently, as illustrated in FIG. 16B, an organic resin film 51 having connection holes 50A is formed on the first inorganic insulating film 52, in a manner similar to the first embodiment.

Next, as illustrated in FIG. 15, in a manner similar to the first embodiment, a source electrode 60S and a drain electrode 60D are connected to the low-resistance regions 21 of a source region 20S and a drain region 20D, via the connection holes 50A. This completes the thin film transistor 2.

In the present embodiment, the first inorganic insulating film 52 and the metal film 52A not completely oxidized are removed by etching, and the interlayer insulating film 50 is formed of only the organic resin film 51 and thus, it is possible to further reduce a leakage current as compared to the first embodiment.

It is to be noted that the present embodiment has been described for the case in which the low-resistance region 21 is formed by oxidization of the metal film 52A, but the low-resistance region 21 may be formed by using plasma, like the modification 2. Further, the low-resistance region 21 may be formed by using diffusion of hydrogen from a silicon nitride film, like the modification 3.

### THIRD EMBODIMENT

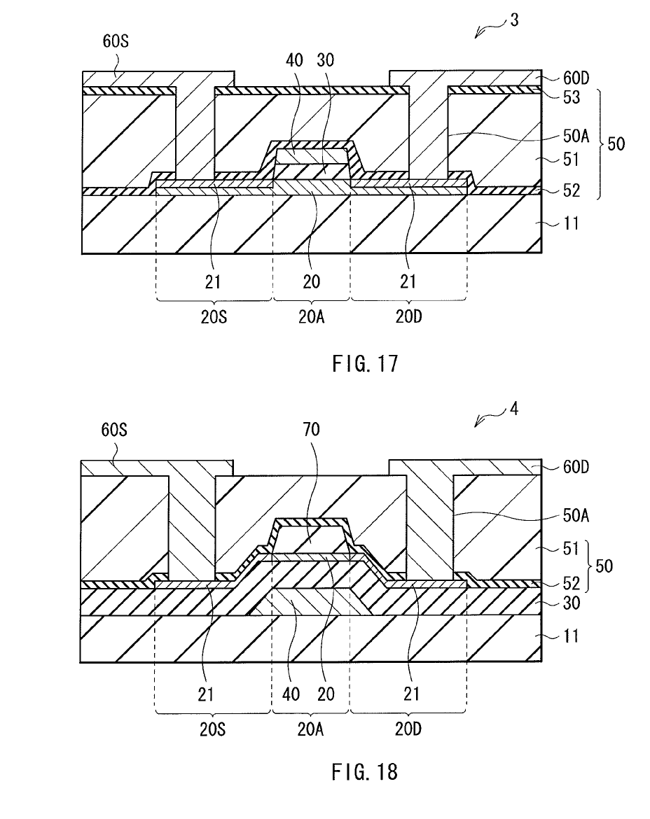

FIG. 17 illustrates a cross-sectional structure of a thin film transistor 3 according to the third embodiment of the present disclosure. This thin film transistor 3 has a configuration similar to that of the thin film transistor 1 in the first embodiment, except that an interlayer insulating film 50 is formed by laminating a first inorganic insulating film 52, an organic resin film 51, and a second inorganic insulating film 53 in this order from a side where an oxide semiconductor film 20 is provided.

The second inorganic insulating film 53 is intended to suppress mixture and diffusion of water into the oxide semiconductor film 20 like the first inorganic insulating film 52, and to further improve reliability of the thin film transistor 3. It is desirable that the second inorganic insulating film 53 have a thickness of around 10 to 100 nm, and be made of aluminum oxide, for example.

This thin film transistor 3 may be formed in a manner similar to the first embodiment, except the followings. After the organic resin film 51 is formed, the second inorganic insulating film 53 having the above-mentioned thickness and made of the above-mentioned material is formed on the organic resin film 51 by, for example, a sputtering method. Subsequently, connection holes 50A are formed in the first inorganic insulating film 52 and the second inorganic insulating film 53 and then, a source electrode 60S and a drain electrode 60D are connected to low-resistance regions 21 of a source region 20S and a drain region 20D, via the connection holes 50A.

In this way, in the present embodiment, the interlayer insulating film 50 is formed by laminating the first inorganic insulating film 52, the organic resin film 51, and the second inorganic insulating film 53 in this order from the side where the oxide semiconductor film 20 is provided and thus, it is possible to further improve reliability of the thin film transistor 3.

### FOURTH EMBODIMENT

FIG. 18 illustrates a cross-sectional configuration of a thin film transistor 4 according to the fourth embodiment of the present disclosure. This thin film transistor 4 is a bottom-gate thin film transistor in which a gate electrode 40, a gate insulating film 30, an oxide semiconductor film 20, a channel protective film 70, an interlayer insulating film 50 (a first inorganic insulating film 52 and an organic resin film 51), and a source electrode 60S as well as a drain electrode 60D are laminated in this order on a substrate 11. Otherwise, this thin film transistor 4 has a configuration similar to that of the thin film transistor 1 of the first embodiment. Therefore, equivalent elements are provided with the same reference characters as those of the first embodiment, and will be described.

The channel protective film 70 is provided on a channel region 20A of the oxide semiconductor film 20, and has, for example, a thickness of around 200 nm, and is a single-layer film or a laminated film made of a silicon oxide film, silicon nitride film, or an aluminum oxide film.

This thin film transistor 4 may be produced as follows, for example. It is to be noted that the same process as that of the first embodiment will be described with reference to the first embodiment.

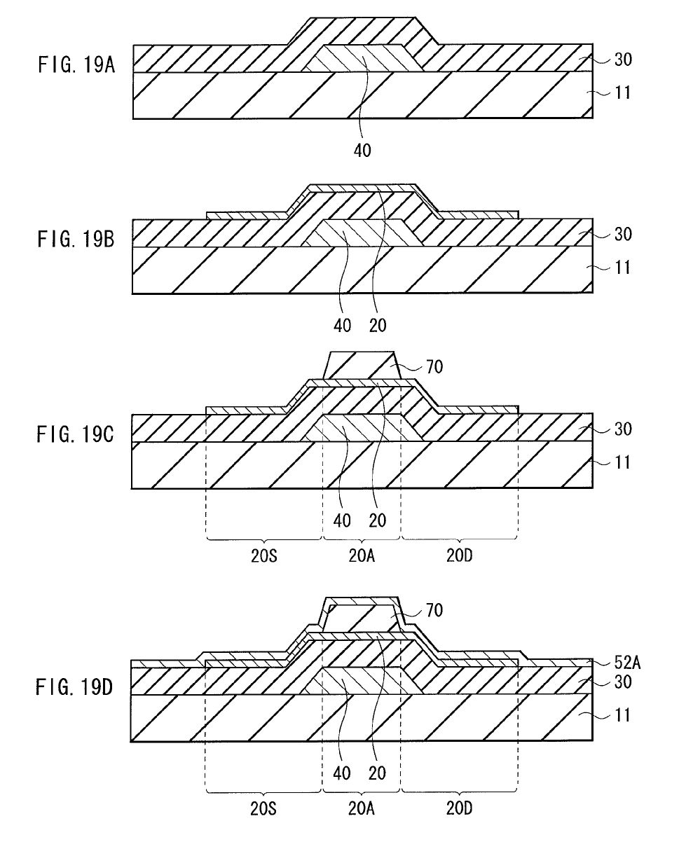

First, on the entire surface in the substrate 11, a molybdenum (Mo) film which becomes a material of the gate electrode 40 is formed by, for example, a sputtering method, evaporation, or the like to have a thickness of around 200 nm. This molybdenum film is patterned by using, for example, photolithography and thereby, the gate electrode 40 is formed as illustrated in FIG. 19A.

Subsequently, as also illustrated in FIG. 19A, on the entire surface of the substrate 11 where the gate electrode 40 is formed, the gate insulating film 30 made of a silicon oxide film or an aluminum oxide film is formed to have a thickness of around 300 nm, by, for example, a plasma CVD method.

Subsequently, as illustrated in FIG. 19B, on the gate insulating film 30, the oxide semiconductor film 20 is formed in a manner similar to the first embodiment.

Next, on the entire surfaces of the oxide semiconductor film 20 and the gate insulating film 30, a channel protective material film that is a single-layer film or a laminated film made of a silicon oxide film, a silicon nitride film, or an aluminum oxide film is formed to have a thickness of around 200 nm. Subsequently, as illustrated in FIG. 19C, the channel protective film 70 is formed in a self-alignment manner near the gate electrode 40, by backside exposure, using the gate electrode 40 as a mask.

After the channel protective film 70 is formed, as illustrated in FIG. 19D, the metal film 52A is formed on the oxide semiconductor film 20 and the channel protective film 70, in a manner similar to the first embodiment.

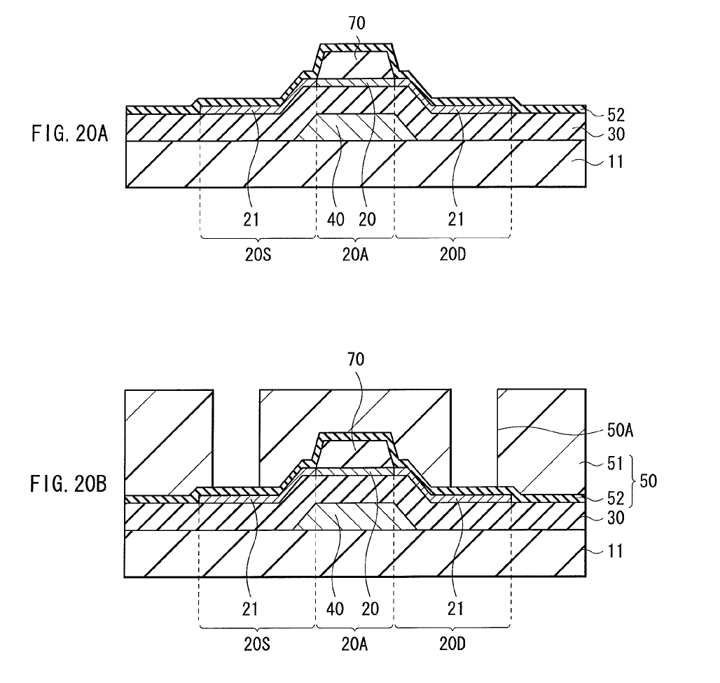

Subsequently, as illustrated in FIG. 20A, in a manner similar to the first embodiment, the metal film 52A is oxidized by a heat treatment and thereby the first inorganic insulating film 52 is formed, and the low-resistance region 21 having an oxygen concentration lower than that of the channel region 20A is formed in a part of each of a source region 20S and a drain region 20D in a depth direction from a top surface.

After the low-resistance region 21 and the first inorganic insulating film 52 are formed, as illustrated in FIG. 20B, the organic material film 51 having connection holes 50A is formed on the first inorganic insulating film 52, in a manner similar to the first embodiment.

After the organic material film 51 is formed, as illustrated in FIG. 18, in a manner similar to the first embodiment, the connection holes 50A are formed in the first inorganic insulating film 52 of the interlayer insulating film 50, and the source electrode 60S and the drain electrode 60D are connected to the low-resistance regions 21 of the source region 20S and the drain region 20D, via the connection hole 50A. This completes the thin film transistor 4 illustrated in FIG. 18.

In this thin film transistor 4, the interlayer insulating film 50 includes the organic resin film 51 and thus, it is possible to increase the thickness of the interlayer insulating film 50, and a step of the channel protective film 70 is securely covered by the interlayer insulating film 50 that is sufficiently thick. Therefore, a failure due to the interlayer insulating film 50 such as disconnection of the source electrode 60S and the drain electrode 60D or a short circuit may be suppressed. Accordingly, it is possible to improve the device characteristics and reliability of the bottom-gate thin film transistor 4 having a self-alignment structure.

### FIFTH EMBODIMENT

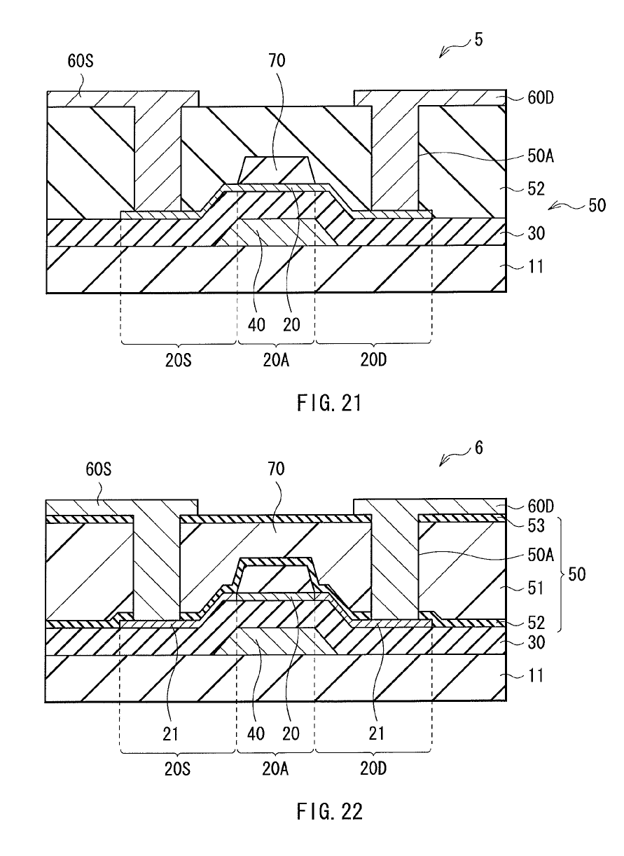

FIG. 21 illustrates a cross-sectional configuration of a thin film transistor 5 according to the fifth embodiment of the present disclosure. This thin film transistor 5 has a configuration similar to that of the thin film transistor 4 in the fourth embodiment, except an interlayer insulating film 50 being formed of only an organic resin film 51, and may be produced similarly. Operation and effect of the thin film transistor 5 are similar to those of the first, second and fourth embodiments.

### Sixth Embodiment

FIG. 22 illustrates a cross-sectional configuration of a thin film transistor 6 according to the sixth embodiment of the present disclosure. This thin film transistor 6 has a configuration similar to that of the thin film transistor 4 in the fourth embodiment, except that an interlayer insulating film 50 is formed by laminating a first inorganic insulating film 52, an organic resin film 51, and a second inorganic insulating film 53 in this order from a side where an oxide semiconductor film 20 is provided. The thin film transistor 6 may be produced in a manner similar to the thin film transistor 4 in the fourth embodiment. Operation and effect of this thin film transistor 6 are similar to those of the first, third, and fourth embodiments.

### (Application Example 1)

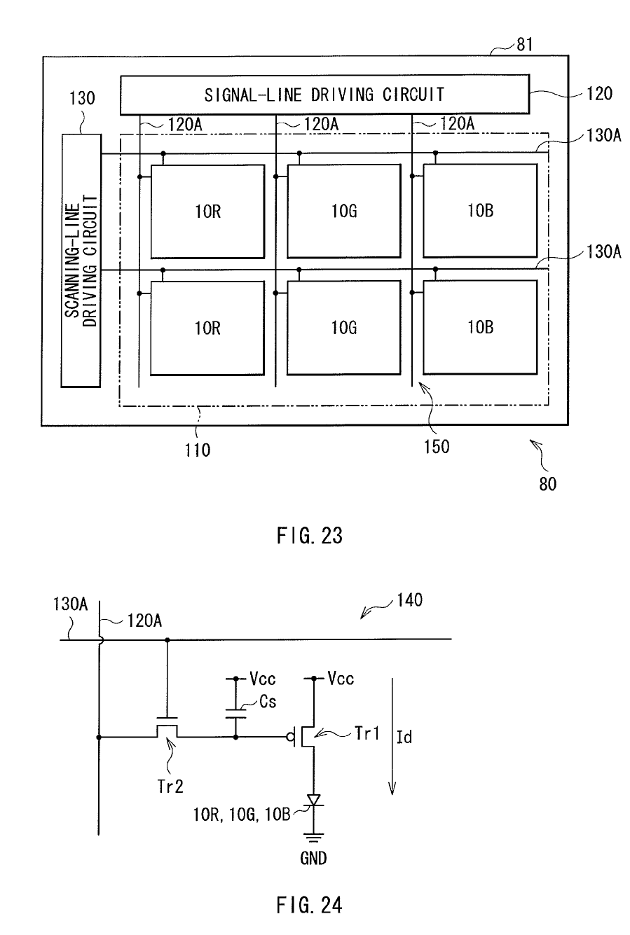

FIG. 23 illustrates a circuit configuration of a display device having any of the thin film transistors 1 to 6, and 1A, as a driving element. A display device 80 is, for example, a liquid crystal display, an organic EL display, or the like, and a plurality of pixels 10R, 10G, and 10B arranged in the form of a matrix and various driving circuits for driving these pixels 10R, 10G, and 10B are formed on a drive panel 81. The pixels 10R, 10G, and 10B are liquid crystal elements, organic EL elements, or the like, which emit red (R) light, green (G) light, and blue (B) light, respectively. These pixels 10R, 10G, and 10B configure one pixel, and a display region 110 includes the plurality of pixels. On the drive panel 81, for example, a signal-line driving circuit 120 and a scanning-line driving circuit 130 serving as drivers for image display, and a pixel driving circuit 150 are disposed as the driving circuits. A sealing panel not illustrated is affixed to this drive panel 81, and the pixels 10R, 10G, and 10B and the driving circuits are sealed with this sealing panel.

FIG. 24 is an equivalent circuit diagram of the pixel driving circuit 150. The pixel driving circuit 150 is an active-type driving circuit in which transistors Tr1 and Tr2 are provided as any of the thin film transistors 1 to 6, and 1A. A capacitor Cs is provided between the transistors Tr1 and Tr2, and the pixel 10R (or the pixel 10G, or 10B) is connected to the transistor Tr1 in series between a first power supply line (Vcc) and a second power supply line (GND). In such a pixel driving circuit 150, signal lines 120A are arranged in columns, and scanning lines 130A are arranged in rows. Each of the signal lines 120A is connected to the signal-line driving circuit 120, and an image signal is supplied from this signal line driving circuit 120 to a source electrode of the transistor Tr2 through the signal line 120A. Each of the scanning lines 130A is connected to the scanning-line driving circuit 130, and a scanning signal is sequentially supplied from this scanning line driving circuit 130 to a gate electrode of the transistor Tr2 through the scanning line 130A. In this display device 80, the transistors Tr1 and Tr2 are formed from any of the thin film transistors 1 and 1A of the embodiments described above and thus, high-quality display is made possible by the thin film transistors 1 and 1A in which parasitic capacitance is small due to the self-alignment structure and the device characteristics and the reliability are improved. Such a display device 80 may be mounted on, for example, any of electronic devices in application examples 2 to 6 described below.

### (Application Example 2)

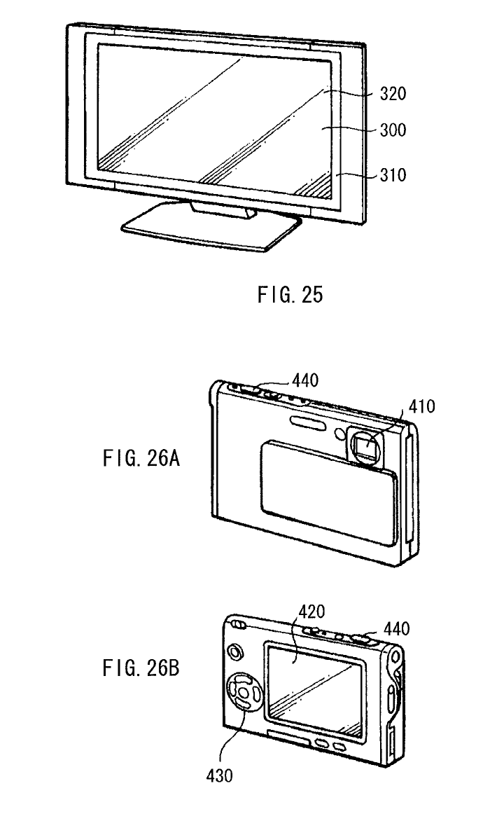

FIG. 25 illustrates an external view of a television receiver. This television receiver has, for example, a video display screen section 300 that includes a front panel 310 and a filter glass 320.

### (Application Example 3)

FIGS. 26A and 26B are external views of a digital still camera. This digital still camera includes, for example, a flash emitting section 410, a display section 420, a menu switch 430, and a shutter button 440.

### (Application Example 4)

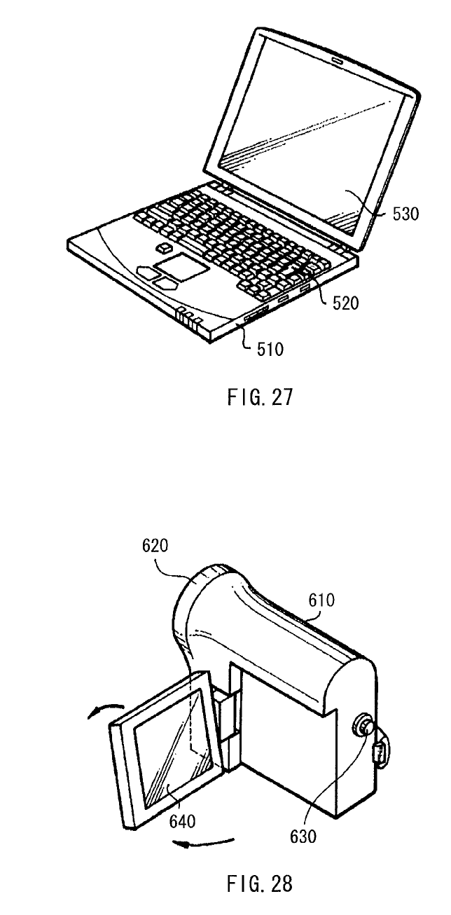

FIG. 27 is an external view of a laptop computer. This laptop computer includes, for example, a main section 510, a keyboard 520 used to enter characters and the like, and a display section 530 displaying an image.

### (Application Example 5)

FIG. 28 is an external view of a video camera. This video camera includes, for example, a main section 610, a lens 620 disposed on a front face of the main section 610 to shoot an image of a subject, a start/stop switch 630 used at the time of shooting, and a display section 640.

### (Application Example 6)

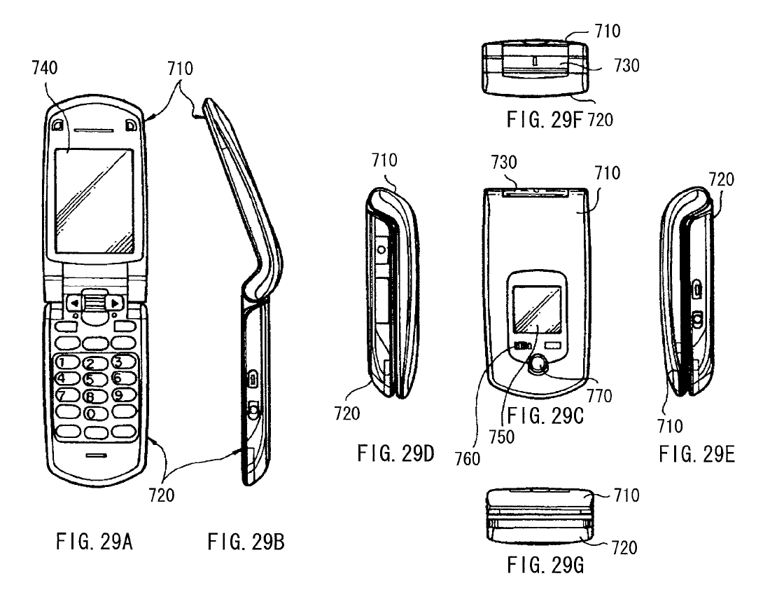

FIGS. 29A through 29G are external views of a portable telephone. This portable telephone includes, for example, an upper housing 710, a lower housing 720, a coupling section (hinge section) 730 that couples the upper and lower housings 710 and 720 to each other, a display 740, a sub-display 750, a picture light 760, and a camera 770.

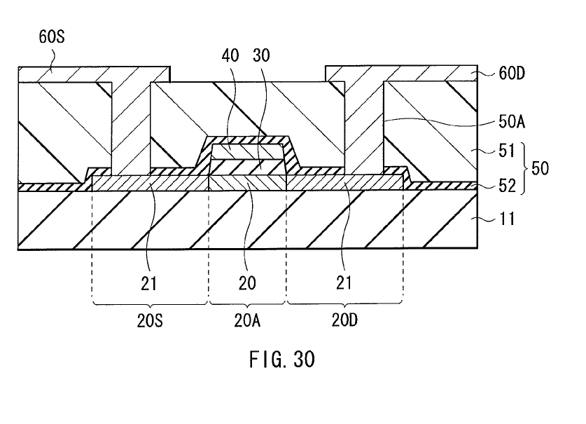

The present disclosure has been described by using the embodiments, but the present disclosure is not limited to these embodiments, and may be variously modified. For example, the embodiments have been described for the case in which the low-resistance region 21 is provided in a part of each of the source region 20S and the drain region 20D in the depth direction from the top surface, but the low-resistance region 21 is sufficient as long as the low-resistance region 21 is provided in at least a part of the source region 20S and the drain region 20D in the depth direction from the top surface. For example, the low-resistance region 21 may be provided in each of the entire source region 20S and the entire drain region 20D in the depth direction from the top surface, as illustrated in FIG. 30.

Further, for example, the embodiments have been described for the case where the oxide semiconductor film 20 is provided directly on the substrate 11, but the oxide semiconductor film 20 may be provided on the substrate 11 with an insulating film such as a silicon oxide film, a silicon nitride film, or an aluminum oxide film in between. This makes it possible to prevent impurities and water from diffusing in the oxide semiconductor film 20 from the substrate 11.

Furthermore, for example, the present disclosure is not limited to the material and the thickness of each layer, or to the film formation method and the film formation condition of each of the embodiments described above, and may employ other materials and thicknesses, or other film formation methods and film formation conditions.

In addition, the present disclosure is applicable to a display device using other display element such as an inorganic electroluminescent element, or an electrodeposition type or electrochromic type display element, other than the liquid crystal display and the organic EL display.

The present disclosure contains subject matter related to that disclosed in Japanese Priority Patent Application JP 2010-152754 filed in the Japan Patent Office on Jul. 5, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof

What is claimed is:

1. A thin film transistor comprising:
a gate electrode;
an oxide semiconductor film having a channel region facing the gate electrode, and having a source region on one side of the channel region, and a drain region on the other side of the channel region;
an interlayer insulating film provided in contact with the oxide semiconductor film as well as having a connection hole, and including an organic resin film; and
a source electrode and a drain electrode connected to the source region and the drain region, respectively, via the connection hole.

2. The thin film transistor according to claim 1, wherein the interlayer insulating film has a layered structure including a first inorganic insulating film and the organic resin film.

3. The thin film transistor according to claim 2, wherein in the interlayer insulating film, the first inorganic insulating film and the organic resin film are laminated in this order from a side where the oxide semiconductor film is provided.

4. The thin film transistor according to claim 3, wherein the first inorganic insulating film is made of an aluminum oxide film, a titanium oxide film or an indium oxide film.

5. The thin film transistor according to claim 4, wherein in the interlayer insulating film, the first inorganic insulating film, the organic resin film, and a second inorganic insulating film are laminated in this order from the side where the oxide semiconductor film is provided.

6. The thin film transistor according to claim 5, wherein
the oxide semiconductor film is provided on a substrate,
the gate insulating film and the gate electrode are provided in this order on the channel region of the oxide semiconductor film and are identical in shape,
the interlayer insulating film is provided on a surface of each of the oxide semiconductor film, the gate insulating film, and the gate electrode, and
the source electrode and the drain electrode are connected to the source region and the drain region, respectively, via the connection hole provided in the interlayer insulating film.

7. The thin film transistor according to claim 1, wherein the oxide semiconductor film has, in at least a part of each of the source region and the drain region in a depth direction from a top surface, a low-resistance region having an oxygen concentration lower than an oxygen concentration of the channel region.

8. The thin film transistor according to claim 7, wherein the low-resistance region is a region in each of the source region and the drain region, at a depth of 10 nm or less in the depth direction from the top surface.

9. The thin film transistor according to claim 1, wherein the oxide semiconductor film has, in at least a part of each of the source region and the drain region in a depth direction from a top surface, a low-resistance region including aluminum as a dopant.

10. The thin film transistor according to claim 1, wherein the oxide semiconductor film is configured to have an amorphous film and a crystallized film laminated in this order from a side where the substrate is provided.

11. The thin film transistor according to claim 10, wherein the crystallized film is made of at least one kind in a group consisting of zinc oxide, indium zinc oxide and indium gallium oxide.

12. A display device comprising:
a thin film transistor and a pixel,
wherein the thin film transistor includes
a gate electrode,
an oxide semiconductor film having a channel region facing the gate electrode, and having a source region on one side of the channel region, and a drain region on the other side of the channel region,
an interlayer insulating film provided in contact with the oxide semiconductor film as well as having a connection hole, and including an organic resin film, and
a source electrode and a drain electrode connected to the source region and the drain region, respectively, via the connection hole.
